(19) United States
(12) Patent Application Publication
(10) Pub. No.: US 2014/0027746 A1
(43) Pub. Date: Jan. 30, 2014

(54) STAR-SHAPED COMPOUNDS FOR ORGANIC SOLAR CELLS

(71) Applicants: Eva Nutz, Hurth (DE); Timo Meyer-Friedrichsen, Krefeld (DE); Andreas Elschner, Mulheim an der Ruhr (DE); Wilfried Lövenich, Bergisch Gladbach (DE); Sergei Anatolievich Ponomarenko, Moscow (RU); Juriy N. Luponosow, Lipetsk (RU)

(72) Inventors: Eva Nutz, Hurth (DE); Timo Meyer-Friedrichsen, Krefeld (DE); Andreas Elschner, Mulheim an der Ruhr (DE); Wilfried Lövenich, Bergisch Gladbach (DE); Sergei Anatolievich Ponomarenko, Moscow (RU); Juriy N. Luponosow, Lipetsk (RU)

(73) Assignee: Heraeus Precious Metals GMBH & Co. KG, Hanau (DE)

(21) Appl. No.: 13/981,535

(22) PCT Filed: Jan. 12, 2012
(86) PCT No.: PCT/EP12/00109

§ 371 Date: Oct. 11, 2013

Related U.S. Application Data
(60) Provisional application No. 61/438,427, filed on Feb. 1, 2011.

(30) Foreign Application Priority Data
Jan. 25, 2011 (DE) 10 2011 009 415.6

(51) Int. Cl. H01L 51/00

(52) U.S. Cl. CPC H01L 51/0068; H01L 51/0065; H01L 51/0071
USPC 257/40; 549/59; 548/126

(57) ABSTRACT

The present invention relates to compounds of the general formula (I) The present invention also relates to a process for the preparation of such compounds, the compounds obtainable by this process, the use of these compounds, semiconducting layers and electronic components.

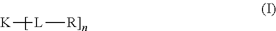

The present invention relates to compounds of the general formula (I)

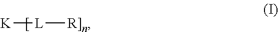

a process for the preparation of such compounds, the compounds obtainable by this process, the use of these compounds, semiconducting layers and electronic components.

Conjugated organic oligomeric compounds can be employed as p or n semiconductors, as is described, for example, in DE-A-10 2004 014 621, DE-A-103 05 945, DE-A-10 2008 014 158 or DE-A-10 2007 046 904. By incorporation of donor and acceptor units in organic oligomeric compounds, the absorption can be shifted into the region of the solar spectrum, so that such compounds can also be employed as a photoactive layer in organic solar cells.

The active layer of an organic solar cell comprises at least one semiconductor component which can be brought into an electronically excited state by absorption of light. From this excited state, at least one electron can be transferred to a second component of the active layer. The electron-releasing component is also called a donor and is distinguished as a hole or p semiconductor. The electron-receiving component is also called an acceptor and is distinguished as an electron or n semiconductor. The efficiency of a solar cell is determined inter alia on the one hand by the efficiency of the charge separation by charge transfer from the donor to the acceptor and on the other hand by the charge transport within the donor or acceptor component to the electrodes of the solar cell. The charge transfer is substantially influenced by the energy levels of the lowest unoccupied molecular orbital (LUMO) of the donor and accepfor material. On the other hand, the charge transport to the electrodes is substantially determined by the morphologies of the active layer. For a charge transport which is as efficient as possible with low recombination rates of the separated charges, a high charge mobility within the individual layer components is necessary, as well as the formation of persistent electronic pathways. This is achieved in particular in polymeric systems such as P3HT/fullerene, in which the formation of an interpenetrating two-phase active layer (bulk heterojunction) with a high interface between the donor (P3HT) and acceptor (fullerene) can be achieved by suitable processing. Such systems achieve efficiencies of 5-6%.

In principle, such morphologies can also be obtained with oligomeric organic compounds in the active layer of organic solar cells. Production can be carried out in this context either from solution or by vapour deposition. Corresponding semiconductors therefore also require, in addition to the requirements of the electronic and optical properties, a good processability by means of which a layer morphology which is as favourable as possible for high efficiencies of the solar cell can be achieved. A good wet processability, by means of which the organic oligomeric compounds are applied to the corresponding substrates from a solution, is desirable in particular here. The wet processability of the organic oligomeric compounds known from the prior art which are employed as semiconductors is, however, still in need of improvement.

The present invention was therefore based on the object of overcoming the disadvantages resulting from the prior art in connection with the use of organic oligomeric compounds as p or n semiconductors.

In particular, the present invention was based on the object of providing organic oligomeric compounds which not only are distinguished by particularly advantageous electronic and optical properties and by a high absorption of sunlight, but which moreover also have a particularly good processability, in particular a particularly good wet processability. Layers produced from such compounds should be characterized by a particularly advantageous photoactivity.

The present invention was also based on the object of providing a process with which such organic oligomeric compounds can be prepared.

A contribution towards achieving the abovementioned objects is made by compounds of the general formula (I)

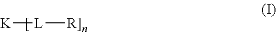

wherein
n is an integer from 3 to 6, where n can assume in particular the value 3, 4, 5 or 6,
R represents H or a non-conjugated chain,
L are linear conjugated units according to the general formula (II)

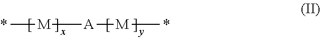

in which
x, y in each case independently of each other represent an integer from 0 to 20, particularly preferably from 0 to 10 and moreover preferably from 0 to 5, but very particularly preferably independently of each other represent 0, 1 or 2,
A represents an acceptor group according to one of the following formulae IIIa-IIIr

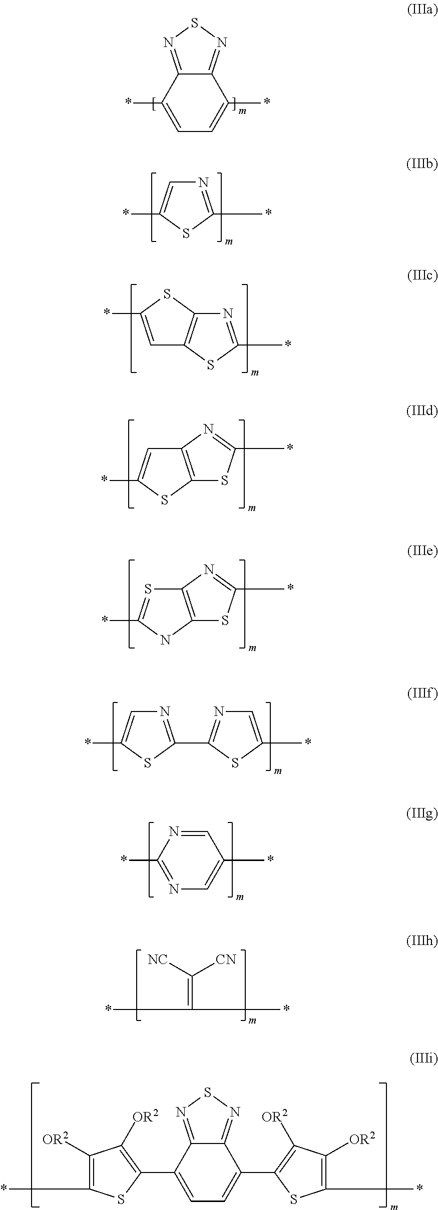

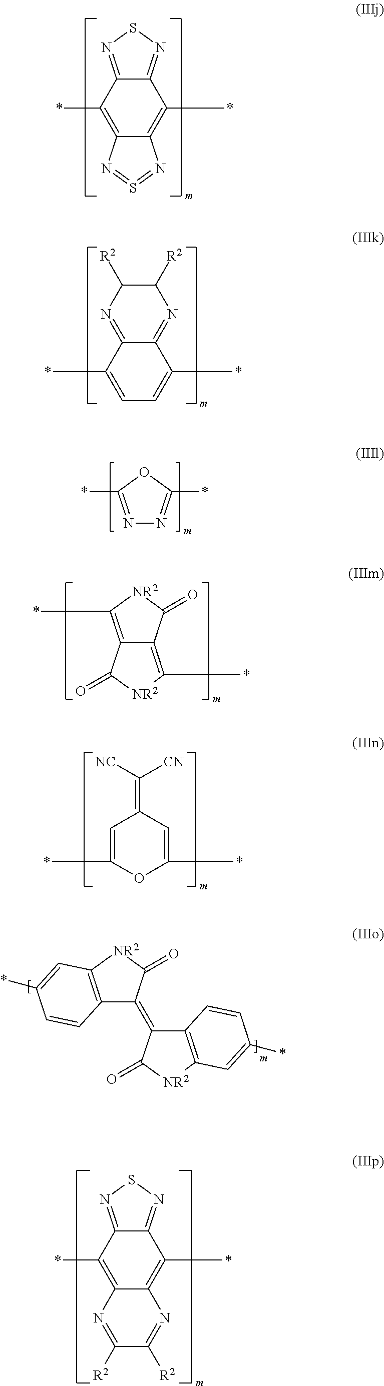

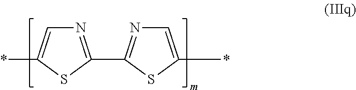

in which
m represents an integer from 1 to 20, particularly preferably from 1 to 10 and most preferably from 1 to 5,
R² represents H or a linear or branched C₁-C₂₀-alkyl group, preferably a C₁-C₁₂-alkyl group, a linear C₁-C₂₀-alkyl group, preferably C₁-C₁₂-alkyl group, which is optionally interrupted by one or more O or S atoms or silylene, phosphonoyl or phosphoryl groups, or an optionally substituted aromatic radical,
   in the case of the acceptor group IIIh R≠H
M represents an aryl compound according to one of the following formulae IVa-IVr

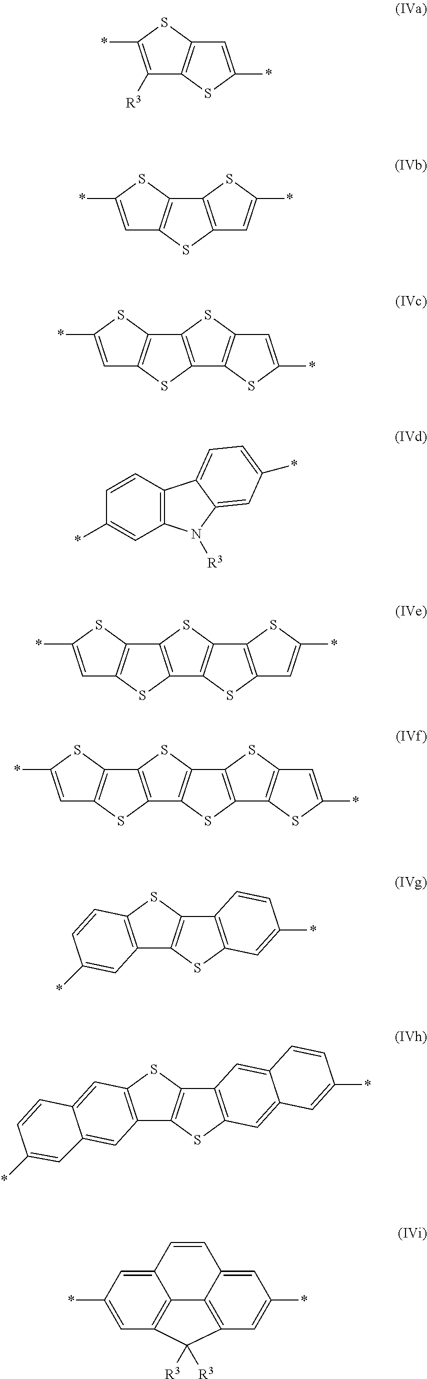

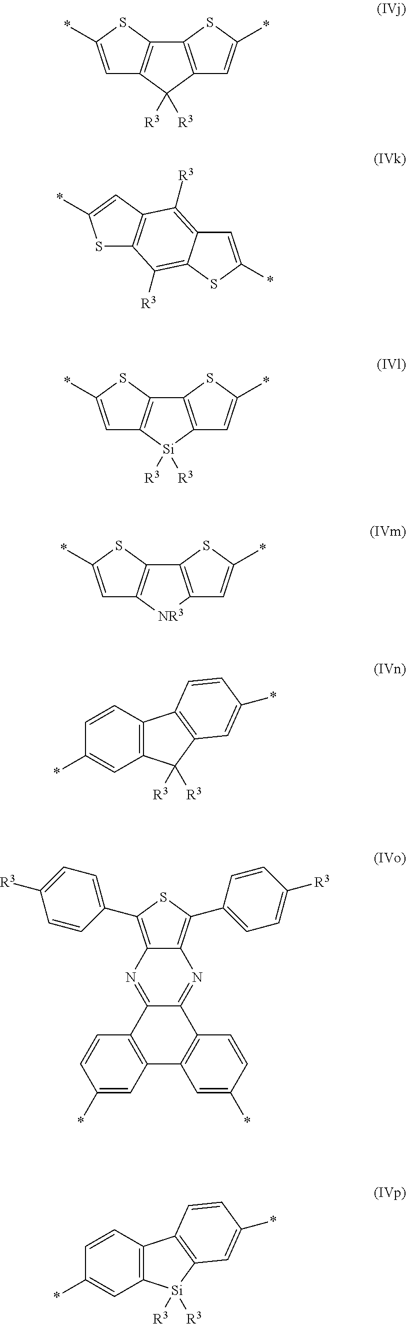

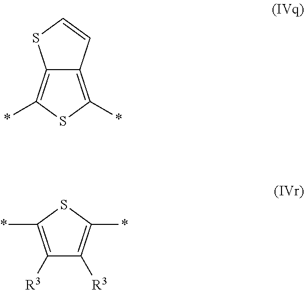

in which
R³ represents H or a linear or branched C₁-C₂₀-alkyl group, preferably a C₁-C₁₂-alkyl group, or a linear C₁-C₂₀-alkyl group, preferably C₁-C₁₂-alkyl group, which is optionally interrupted by one or more O or S atoms or silylene, phosphonoyl or phosphoryl groups, where, if the aryl compound A comprises two radicals R³, these can be identical or different,
K represents a branching group according to one of the following formulae Va-Vt

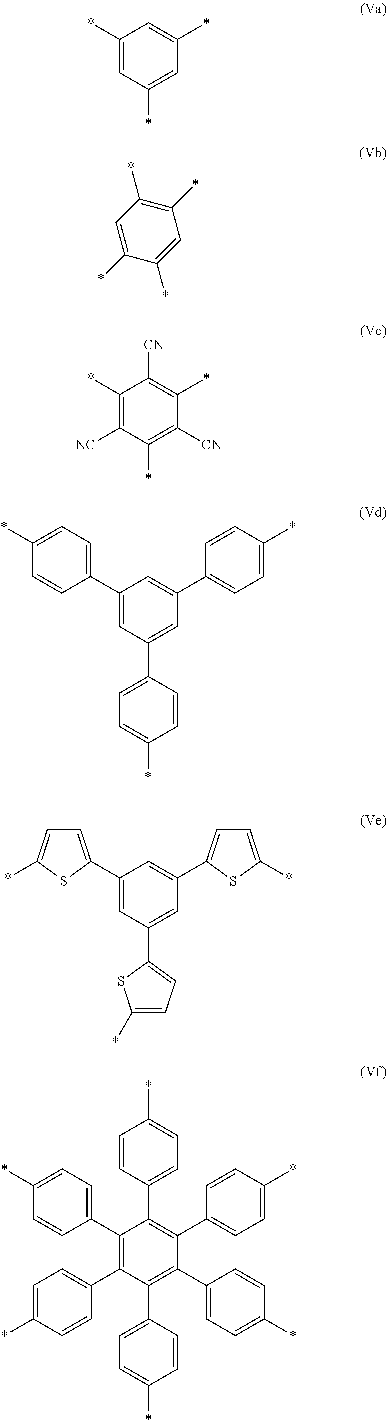

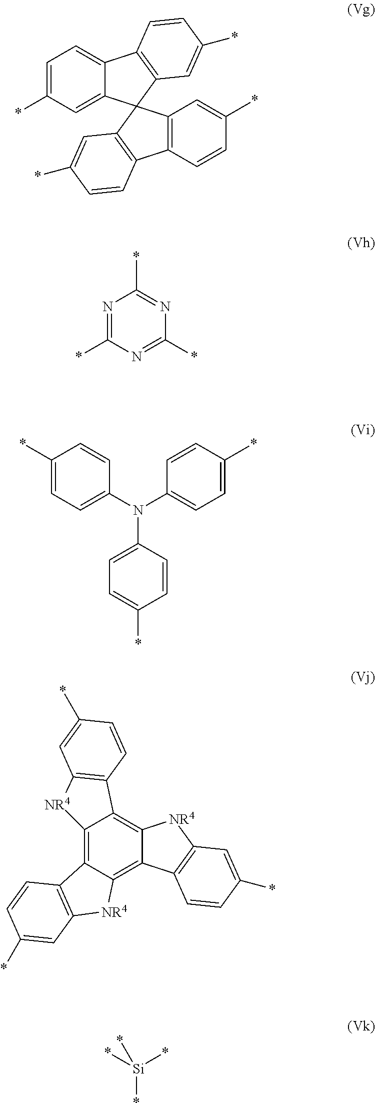

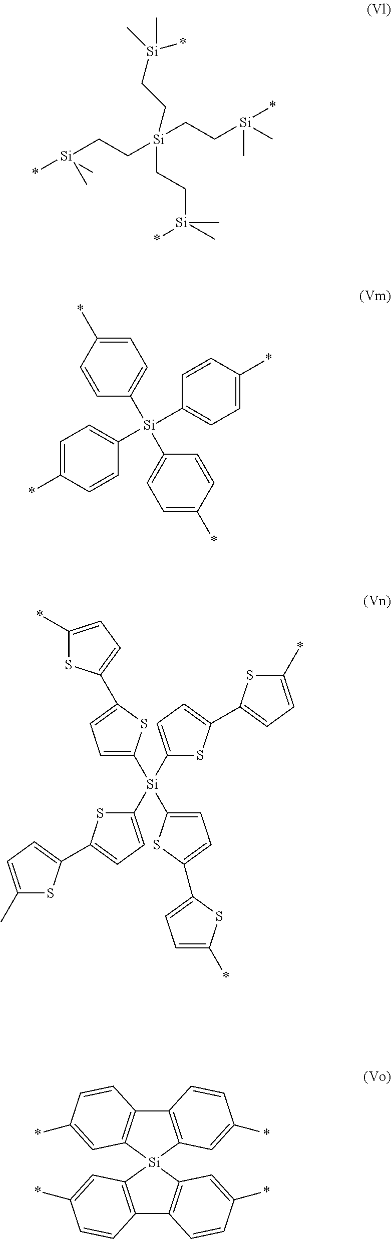

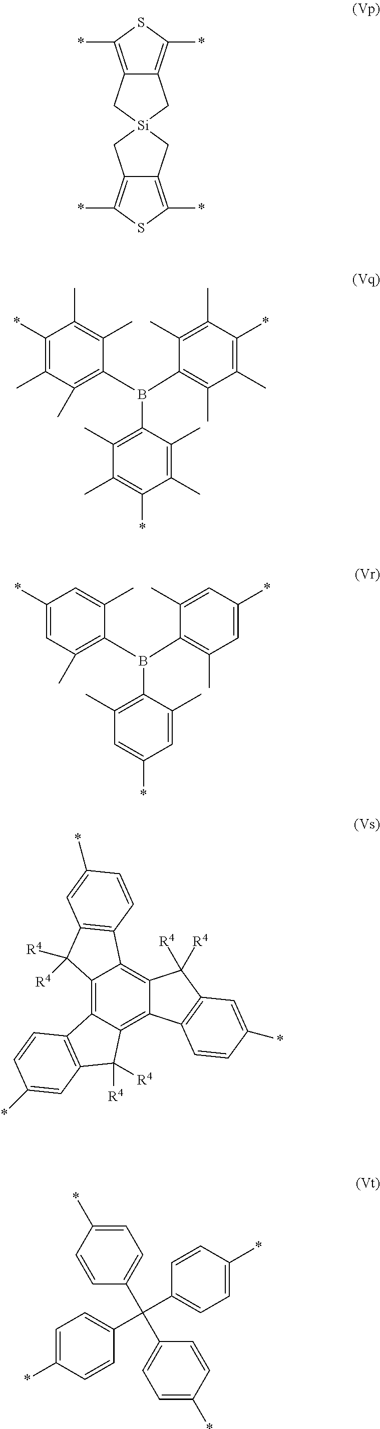

in which
R⁴ represents H or a linear or branched C₁-C₂₀-alkyl group, preferably a C₁-C₁₂-alkyl group, or a linear C₁-C₂₀-alkyl group, preferably C₁-C₁₂-alkyl group, which is optionally interrupted by one or more O or S atoms or silylene, phosphonoyl or phosphoryl groups.

The positions labelled with * in the formulae (II), (IIIa)-(IIIr), (IVa)-(IVr) and (Va)-(Vt) in each case identify the linkage sites. In the case of the formula (II), these are the bonding sites in which a linkage of the linear conjugated units L with the branching group K (via the structural element -[M]ₓ- if x>0 or via the structural element -A- if x=0) and the outer radical R (via the structural element -[M]_{y}- if y>0 or via the structural element -A- if y=0) takes place. In the case of the formulae (IIIa)-(IIIt), these are the bonding sites in which a linkage of the acceptor group A with the structural element -[M]ₓ- (if x>0) or the branching group K (if x=0) or the structural element -[M]_{y}- (if y>0) or the radical R (if y=0) takes place. In the case of the formulae (IVa)-(IVs), these are the bonding sites in which in the case of the structural element -[M]ₓ- a linkage of the unit M with the branching group K and with the acceptor group A or with a further unit M (if x>1) takes place, and in the case of the structural element -[M]_{y}- a linkage of the unit M with the acceptor group A or a further unit M (if y>1) and the radical R takes place. In the case of the formulae (Va)-(Vt), these are the bonding sites in which a linkage of the branching group K with the structural element -[M]ₓ- (if x>0) or the acceptor group A (if x=0) takes place.

The compounds according to the invention preferably have a so-called “core-shell structure”, in which the branching group K forms the core and the units -L-R bonded to the core form the shell. The compounds can in principle be oligomers or polymers.

In the context of the invention, the core-shell structure is a structure at the molecular level, i.e. it relates to the structure of a molecule as such.

The compounds according to the invention have, if n is, for example, 3, 4 or 6, a structure according to the following formulae (I-3), (I-4) or (I-6):

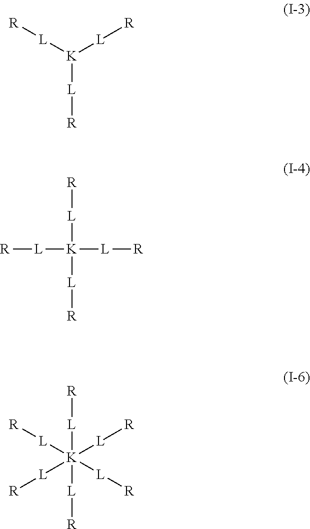

in which K, L and R have the abovementioned meaning.

The radical R is preferably a non-conjugated chain. Preferred non-conjugated chains are those which have a high flexibility, i.e. a high (intra)molecular mobility, as a result interact readily with solvent molecules and thus generate an improved solubility. In the context of the invention, flexible is to be understood in the sense of (intra)molecularly mobile. The non-conjugated chains (R) are straight-chain or branched aliphatic, unsaturated or araliphatic chains which have 1 to 20 carbon atoms, preferably which have 1 to 12 carbon atoms, and are optionally interrupted by oxygen, or C₃-C₈-cycloalkylenes. Aliphatic and oxyaliphatic groups, i.e. alkoxy groups, or straight-chain or branched aliphatic groups, in particular C₁-C₂₀-alkyl groups, interrupted by one or more oxygen or sulphur atoms or silylene, phosphonyl or phosphoryl groups, are preferred. Linear or branched C₁-C₂₀-alkyl groups, in particular C₁-C₁₂-alkyl groups, are particularly preferred according to the invention as radicals R. Examples of suitable radicals R are alkyl groups, such as n-hexyl, n-heptyl, n-octyl, n-nonyl, n-decyl and n-dodecyl groups, and alkoxy groups, such as n-hexyloxy, n-heptyloxy, n-octyloxy, n-nonyloxy, n-decyloxy and n-dodecyloxy groups, or C₃-C₈-cycloalkylenes, such as cyclopentyl, cyclohexyl or cycloheptyl.

Compounds of the general formula (I) which are particularly preferred according to the invention are those in which the structural elements M in the linearly conjugated chains L comprise optionally substituted 2,5-thienylene (IVr)

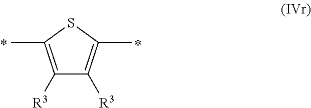

wherein the radicals R³ can be identical or different and represent H or a linear or branched C₁-C₂₀-alkyl group, preferably a C₁-C₁₂-alkyl group, or a linear C₁-C₂₀-alkyl group, preferably C₁-C₁₂-alkyl group, which is optionally interrupted by one or more O or S atoms or silylene, phosphonoyl or phosphoryl groups. In this connection, structural elements M in which R³ in each case represents a hydrogen atom are very particularly preferred. In this context, the structural units M can be present as monomers (in this case x and y have the value 1)

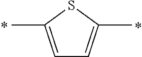

or as dimers (in this case x and y have the value 2)

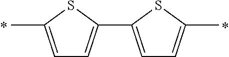

According to a particular embodiment of the compounds of the general formula (I) according to the invention, the branching group K represents a branching group of the formula (Ve), (Vg) or (Vi)

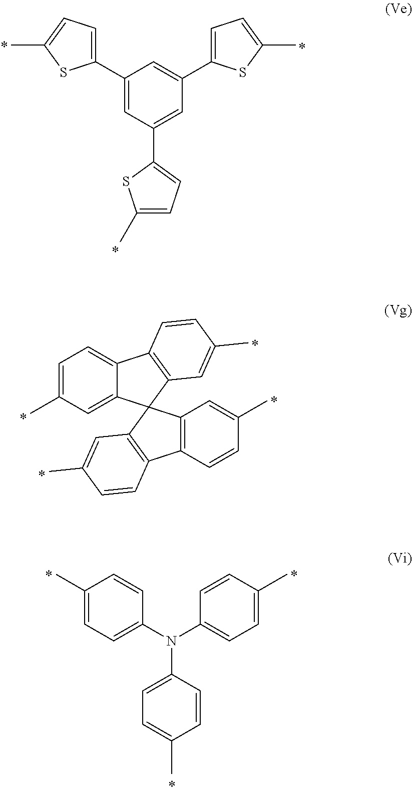

where the branching group of the formula (Vi) is very particularly preferred.

According to a first development of this particular embodiment of the compounds according to the invention,

M represents 2,5-thienylene (IVr)

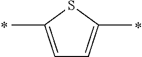

x represents 2;

y represents 0;

A represents an acceptor group of the formula (IIIh)

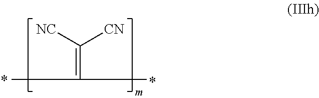

in which m represents 1; and
R represents a —C₆H₁₃ radical.

According to a second development of this particular embodiment of the compounds according to the invention,

M represents 2,5-thienylene (IVr)

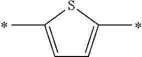

x represents 1;
y represents 2;
A represents an acceptor group of the formula (IIIa)

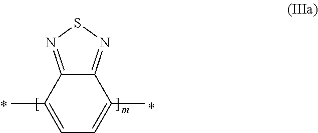

in which m represents 1; and
R represents a radical

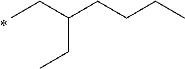

Layers of the compounds of the general formula (I) according to the invention are preferably conductive or semiconducting. The invention particularly preferably provides those layers of the compounds or mixtures which are semiconducting. Those layers of the compounds which have a mobility for charge carriers of at least 10⁴ cm²/Vs are particularly preferred. Charge carriers are e.g. positive hole charges.

The compounds according to the invention are typically readily soluble in the commonly available organic solvents and are therefore outstandingly suitable for processing from solution. Solvents which are suitable in particular are aromatics, ethers or halogenated aliphatic hydrocarbons, such as, for example, chloroform, toluene, benzene, xylenes, diethyl ether, methylene chloride, chlorobenzene, dichlorobenzene or tetrahydrofuran, or mixtures of these. The compounds according to the invention are conventionally soluble in these solvents to the extent of at least 0.1 wt. %, preferably at least 1 wt. %, particularly preferably at least 5 wt. %. The compounds according to the invention form high quality layers of uniform thickness and morphology from evaporated solutions and are therefore suitable for electronic uses, in particular as a semiconductor layer in organic solar cells.

A contribution towards achieving the abovementioned objects is also made by a process for the preparation of the compounds according to the invention, wherein
the -[L-R] radical or radicals or synthesis precursors of the -[L-R] radical or radicals are present as an organoboron compound and the branching group K is present as an aryl or heteroaryl halide, or
the -[L-R] radical or radicals or synthesis precursors of the -[L-R] radical or radicals are present as an aryl or heteroaryl halide and the branching group K is present as an organoboron compound,
   and the -[L-R] radical or radicals or synthesis precursors of the -[L-R] radical or radicals are bonded to the branching group K via a Suzuki coupling.

In this context, “synthesis precursor of the -[L-R] radical or radicals” is understood as meaning, for example, compounds which obtain their final structure only after coupling with the branching group K. Thus, for example, the acceptor groups A in the linearly conjugated units L can be completed only after coupling of the synthesis precursors with the branching group K. It is also conceivable to attach the structural element -[M]_{y}-R or only the radical R only after coupling of the synthesis precursors with the branching group K.

According to a first particular embodiment of the process according to the invention, the organoboron compound employed is either a compound of the general formula (VI) or a compound of the general formula (VII)

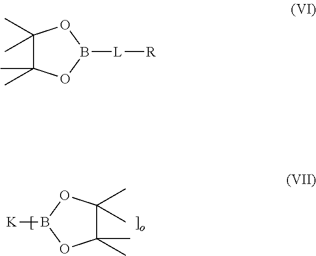

in which K, L and R have the meaning described above and in which o represents an integer from 3 to 6, where o in particular can assume the value 3, 4, 5 or 6.

In connection with the particular embodiment described above for the process according to the invention, it is furthermore preferable for the aryl or heteroaryl halide employed to be either a compound of the general formula (VIII) or a compound of the general formula (IX)

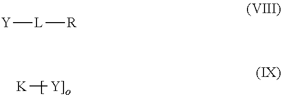

in which K, L and R have the meaning described above, o represents an integer from 1 to 5 and Y represents Cl, Br, I or —O—SO₂—R⁶, wherein R⁶ represents a methyl, trifluoromethyl, phenyl or tolyl group.

Suzuki coupling is described inter alia in Suzuki et al., Chem. Rev. 1995, 95, 2457-2483. In a preferred embodiment of the process according to the invention, the coupling is carried out in the presence of at least one base and/or at least one catalyst which comprises a metal of sub-group VIII of the periodic table of the elements, in the following called metal of sub-group VIII for short.

The preferred embodiment of the process according to the invention is carried out at a temperature of from +20° C. to +200° C., preferably from +40° C. to +150° C., particularly preferably from +80° C. to +130° C., in an organic solvent or solvent mixture.

Possible catalysts which comprise a metal of sub-group VIII are in principle all suitable compounds which comprise a metal of sub-group VIII, preferably Pd, Ni or Pt, particularly preferably Pd. The catalyst(s) are preferably employed in amounts of from 0.05 wt. % to 10 wt. %, particularly preferably from 0.5 wt. % to 5 wt. %, based on the total weight of the compounds to be coupled.

Particularly suitable catalysts are complex compounds of metals of sub-group VIII, in particular complexes of palladium(0) which are stable in air, Pd complexes which be readily reduced with organometallic reagents (e.g. lithium-alkyl compounds or organomagnesium compounds) or phosphines to give palladium(0) complexes, or palladium(2) complexes, optionally with the addition of PPh₃ or other phosphines. For example, PdCl₂(PPh₃)₂, PdBr₂(PPh₃)₂ or Pd(OAc)₂ or mixtures of these compounds, with the addition of PPh₃, can be employed. Pd(PPh₃)₄, without or with the addition of phosphines, in a preferred embodiment without the addition of phosphines, which is available in an inexpensive form, is preferably employed. PPh₃, PEtPh₂, PMePh₂, PEt₂Ph or PEt₃ are preferably employed as phosphines, particularly preferably PPh₃. However, it is also possible to employ as catalysts palladium compounds without the addition of phosphine, such as, for example, Pd(OAc)₂. Phase transfer catalysts are furthermore suitable as catalysts.

Bases which are employed are, for example, hydroxides, such as e.g. NaOH, KOH, LiOH, Ba(OH)₂, Ca(OH)₂, alkoxides, such as e.g. NaOEt, KOEt, LiOEt, NaOMe, KOMe, LiOMe, alkali metal salts of carboxylic acids, such as e.g. sodium, potassium or lithium carbonate, hydrogencarbonate, acetate, citrate, acetylacetonate, glycinate, or other carbonates, such as e.g. Cs₂CO₃ or Tl₂CO₃, phosphates, such as e.g. sodium phosphate, potassium phosphate or lithium phosphate, or mixtures of these. Sodium carbonate is preferably employed. The bases can be employed as solutions in water or as suspensions in organic solvents, such as toluene, dioxane or DMF. Solutions in water are preferred, since the products obtained can thus be easily separated off from the reaction mixture due to their low solubility in water.

It is also possible to employ further salts, such as, for example, LiCl or LiBr, as auxiliary substances.

Suitable solvents for the coupling reaction are, for example, alkanes, such as pentane, hexane and heptane, aromatics, such as benzene, toluene and xylenes, compounds comprising ether groups, such as dioxane, dimethoxyethane and tetrahydrofuran, and polar solvents, such as dimethylformamide or dimethylsulphoxide. Aromatics are preferably employed as solvents in the process according to the invention. Toluene is very particularly preferred. It is also possible to employ mixtures of two or more of these solvents as the solvent.

Working up of the reaction mixture is carried out by methods known per se, e.g. by dilution, precipitation, filtration, extraction, washing, recrystallization from suitable solvents, chromatography and/or sublimation. For example, working up can be carried out in a manner in which when the reaction is complete the reaction mixture is poured into a mixture of acidic (ice-) water, e.g. prepared from 1 molar hydrochloric acid, and toluene, the organic phase is separated off, washing with water is carried out, and the product comprised as a solid is filtered off, washed with toluene and then dried in vacuo. The compounds of the general formula (I) can already be obtained in a high quality and purity without further subsequent purification processes and are semiconducting. However it is possible to purify these products further by known methods, e.g. by recrystallization, chromatography or sublimation.

A contribution towards achieving the abovementioned objects is also made by the compounds obtainable by the process described above.

A contribution towards achieving the abovementioned objects is also made by the use of the compounds according to the invention for the production of semiconducting layers for electronic components, but in particular for the production of semiconducting layers in organic solar cells. For use, the compounds according to the invention are applied to suitable substrates, for example to silicon wafers, polymer films or glass panes provided with electrical or electronic structures. All application processes are possible in principle for the application. Preferably, the compounds and mixtures according to the invention are applied from a liquid phase, i.e. from solution, and the solvent is then evaporated. The application from solution can be carried out by the known methods, for example by spraying, dipping, printing and knifecoating. Application by spin coating and by ink jet printing is particularly preferred. In this connection it is furthermore particularly preferable for the compounds according to the invention to be employed as a donor group in combination with fullerenes as an acceptor group.

The layers produced from the compounds according to the invention can be modified further after the application, for example by a heat treatment, e.g. passing through a liquid crystal phase, or for structuring e.g. by laser ablation.

A contribution towards achieving the abovementioned objects is also made by semiconducting layers which comprise the compounds according to the invention. According to a preferred embodiment of the semiconducting layer according to the invention, this comprises the compounds according to the invention as a donor group and fullerenes as an acceptor group, the weight ratio of compound according to the invention to fullerene preferably being in a range of from 10:1 to 1:10, particularly preferably in a range of from 2:1 to 1:5 and most preferably in a range of from 1:1 to 1:3.

A contribution towards achieving the abovementioned objects is moreover made by an electronic component comprising at least one semiconducting layer according to the invention. Preferred electronic components in this context are, in particular, organic solar cells.

The invention is now explained in more detail with the aid of non-limiting examples.

Glass equipment was dried in an oven at 150° C. for one hour, assembled in the hot state and cooled under an inert gas (argon). Unless mentioned otherwise, exclusively anhydrous solvents were used. 2-Isopropoxy-4,4,5,5-tetramethyl-1,3,2-dioxaborolane, N-bromosuccinimide, n-butyllithium solution, bis(dibenzylideneacetone)palladium, potassium acetate, tetrakis(triphenylphosphine)palladium(0), malonic acid dinitrile, ethylene glycol, heptanoyl chloride and 4,4,4′,4′,5,5,5′,5′-octamethyl-2,2′-bi(1,3,2-dioxaborolane) were obtained from SigmaAldrich Co.

2-(2-Ethylhexyl)thiophene and 2,7-(thien-2-yl)-2,1,3-benzothiadiazole (see US 2004/0229925 A1), 2-(2-bromothien-5-yl)-7-(thien-2-yl)-2,1,3-benzothiadiazole (see Organic Letters 2009, 11, 863-866) and tris {4-(4,4,5,5-tetramethyl-[1,3,2]dioxaborolane)phenyl}amine (see Jens Cremer, Peter Bauerle, Journal of Materials Chemistry, 2006,16,874-884) were prepared analogously to the literature cited here.

### EXAMPLE 1

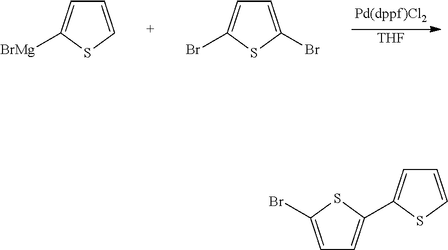

A solution of 2-bromothiophene (83.15 g, 0.51 mol) in 400 ml of THF was added dropwise to a suspension of magnesium filings (13.37 g, 0.55 mol) in 100 ml of THF in the course of 1 hour such that the solution boiled gently. The mixture was then heated under reflux for a further 4 hours. The Grignard solution obtained was added dropwise at room temperature to a solution of 2,5-dibromothiophene (120.97 g, 0.5 mol) and [bis(diphenylphosphino)ferrocene]dichloropalladium(II) (4.08 g, 0.005 mol) in 500 ml of THF and the mixture was then boiled under reflux for 16 hours. The reaction mixture was stirred into 2,000 ml of ice-cooled water containing 600 ml of 1M HCl solution. The organic phase was separated off and the aqueous phase was extracted twice with 300 ml of MTBE each time. The combined organic phases were washed twice with 250 ml of water each time, dried over sodium sulphate and filtered. The solvent was evaporated in vacuo and the crude product obtained was distilled over a Vigreux column (0.2 mbar, 107-110° C. fraction). Yield: 45.9 g (37.5%) of product as a colourless solid which crystallized at room temperature (purity according to GC-MS>99%). ¹H NMR (250 MHz, CDCl₃, δ ppm): 6.91 (d, 1H, J=3.8 Hz), 6.97 (d, 1H, J=3.8 Hz), 7.01 (dd, 1H, J=3.6 Hz, J=5.1 Hz), 7.11 (dd, 1H, J=1.2 Hz, J=3.6 Hz), 7.23 (dd, 1H, J=1.2 Hz, J=5.1 Hz).

### EXAMPLE 2

### 1-(2,2′-Bithien-5-yl)heptan-1-one

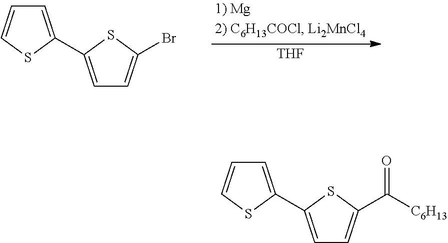

A solution of 5-bromo-2,2′-bithiophene (10.5 g, 42.8 mmol) in 110 ml of THF was added dropwise to a suspension of magnesium filings (1.04 g, 43.7 mmol) in 10 ml of THF. The Grignard solution was boiled under reflux for 2 hours, subsequently cooled to room temperature and added dropwise to a solution of heptanoyl chloride (6.34 g, 34 mmol) and freshly prepared Li₂MgCl₄ (1.07 mmol) at 0° C. The mixture was subsequently warmed to room temperature in the course of 2 hours and then stirred further for one hour. Li₂MgCl₄ was prepared from MgCl₂ (135 mg, 1.07 mmol) and LiCl (95 mg, 2.24 mmol) by stirring in 15 ml of THF at room temperature for 2 hours.

The reaction solution was added to 400 ml of water and 600 ml of diethyl ether. The organic phase was separated off and washed with water, dried over sodium sulphate and filtered. The solvent was evaporated in vacuo and the residue was dried in vacuo. 12.1 g of crude product with a content of 98% (measured by GPC) were obtained. Chromatography over silica gel (mobile phase: toluene-hexane 1:1) resulted in a pure product (yield: 10.70 g, 94%). ¹H NMR (250 MHz, CDCl₃, δ ppm): 0.88 (t, 3H, J=6.7 Hz), 1.20-1.45 (overlapping signals, 6H), 1.73 (m, 2H, M=5, J=7.3 Hz), 2.85 (t, 2H, J=7.3 Hz), 7.15 (d, 1H, J=3.7 Hz), 7.30 (s, 1H), 7.28-7.33 (overlapping signals, 2H), 7.58 (d, 1H, J=4.3 Hz). ¹³C NMR (125 MHz, CDCl₃): (δ [ppm] 14.03, 22.48, 24.85, 28.99, 31.58, 39.02, 124.06, 125.48, 126.33, 128.18, 132.48, 136.38, 142.32, 145.24, 193.27. Calculated (%) for C₁₅H₁₈OS₂: C, 64.71; H, 6.52; S, 23.03. Found: C, 64.89; H, 6.61; S, 22.79.

### EXAMPLE 3

### 2-(2,2′-Bithien-5-yl)-2-hexyl-1,3-dioxolane

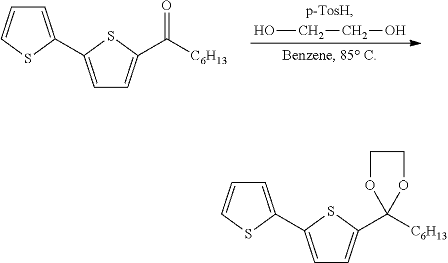

1-(2,2′-Bithien-5-yl)heptan-1-one (10.0 g, 35.9 mmol) was dissolved in hot anhydrous benzene (350 ml). When dissolution was complete, 4-toluenesulphonic acid (p-TosH) (1.37 g, 7.2 mmol) and ethylene glycol (80 ml, 89 g, 1.44 mol) were added. The solution was then boiled at 110° C. for 18 hours using a water separator. Thereafter, a saturated aqueous sodium hydrogencarbonate solution was added and the mixture was extracted with 3×300 ml of toluene. The combined organic phases were dried over sodium sulphate and filtered. The solvent was evaporated in vacuo and the residue was dried in vacuo. 11.79 g of crude product were obtained with a product content of 80% (according to ¹H NMR analysis). The crude product was purified by chromatography over silica gel (eluent: toluene) and recrystallized from hexane (yield: 8.35 g, 72%). ¹H NMR (250 MHz, CDCl₃, δ ppm): 0.87 (t, 3H, J=6.7 Hz), 1.18-1.48 (overlapping signals, 8H), 1.99 (t, 2H, J=7.3 Hz), 3.93-4.08 (overlapping signals, 4H), 6.88 (d, 1H, J=3.7 Hz), 6.97-7.03 (overlapping signals, 3H), 7.12 (dd, 1H, J=1.2 and 2.4 Hz), 7.18 (dd, 1H, J=1.2 and 4.3 Hz). ¹³C NMR (125 MHz, CDCl₃): δ [ppm] 14.06, 22.55, 23.68, 29.25, 31.71, 40.55, 64.97, 108.98, 123.34, 123.52, 124.28, 125.00, 127.75, 136.86, 137.38, 147.71. Calculated (%) for C₁₇H₂₂O₂S₂: C, 63.32; H, 6.88; S, 19.89. Found: C, 63.55; H, 6.94; S, 19.75.

### EXAMPLE 4

### 2-[5′-(2-Hexyl-1,3-dioxolan-2-yl)-2,2′-bithien-5-yl]-4,4,5,5-tetramethyl-1,3,2-dioxaborolane

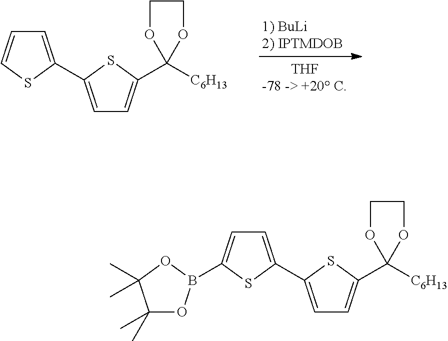

A 1.6 M solution of n-butyllithium (15.70 ml, 25.1 mmol) in hexane was added dropwise at −78° C. to a solution of 2-(2,2′-bithien-5-yl)-2-hexyl-1,3-dioxolane (8.10 g, 25.1 mmol) in 250 ml of THF. The reaction solution was stirred at −78° C. for 60 minutes. 2-Isopropoxy-4,4,5,5-tetramethyl-1,3,2-dioxaborolane (5.124 ml, 25.1 mmol) was then added in one portion. The reaction solution was stirred at −78° C. for 1 hour, the cooling bath was then removed and the solution was stirred for a further hour. When the reaction was complete, 600 ml of freshly distilled diethyl ether were added. 25 ml of a 1M HCl solution were then added dropwise. The organic phase was separated off, washed with water, dried over sodium sulphate and filtered.

After evaporation of the solvent in vacuo, 11.26 g (95%) of product were obtained (98% purity according to GPC). The product was employed in the subsequent reaction without further purification. ¹H NMR (250 MHz, CDCl₃, δ ppm): 0.84 (t, 3H, J=6.7 Hz), 1.18-1.48 (overlapping signals with a maximum at 1.33 ppm, 20H), 1.99 (t, 2H, J=7.3 Hz), 3.93-4.08 (overlapping signals, 4H), 6.88 (d, 1H, J=3.7 Hz), 7.06 (d, 3H, J=3.7 Hz), 7.18 (d, 1H, J=3.7 Hz), 7.49 (d, 1H, J=3.7 Hz). ¹³C NMR (125 MHz, CDCl₃): δ [ppm] 14.06, 22.54, 23.64, 24.73, 29.24, 31.70, 40.54, 64.99, 84.14, 108.95, 124.05, 124.73, 125.13, 136.72, 137.90, 144.12, 146.44. Calculated (%) for C₂₃H₃₃BO₄S₂: C, 61.60; H, 7.42; S, 14.30. Found: C, 61.45; H, 7.27; S, 14.24.

### EXAMPLE 5

### Tris{4-[5′-(2-hexyl-1,3-dioxolan-2-yl)-2,2′-bithien-5-yl]phenyl}amine

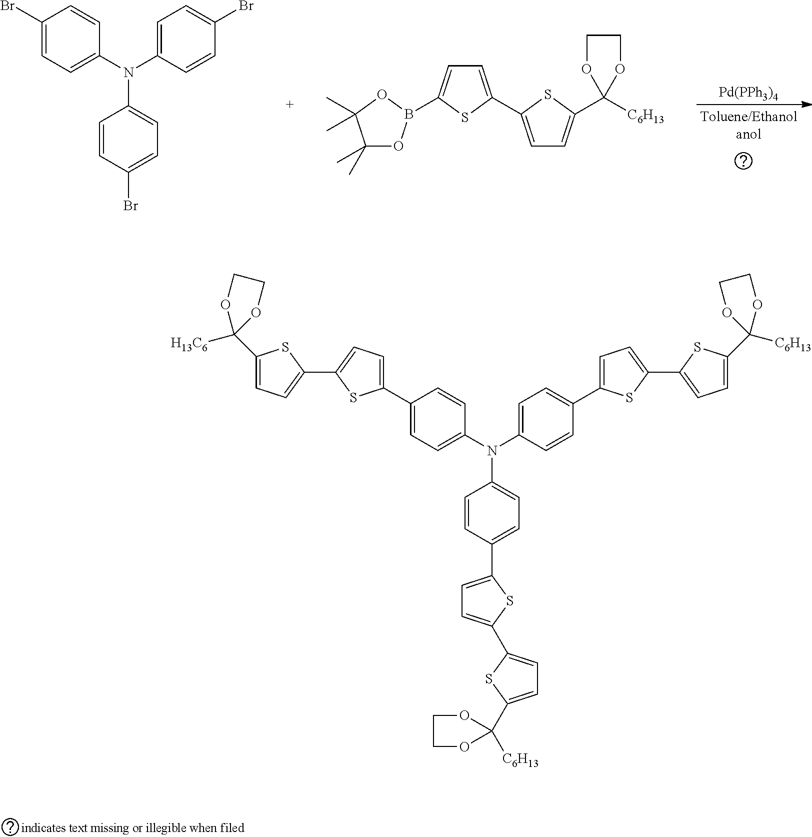

The degassed solutions of tris(4-bromophenyl)amine (1.26 g, 2.61 mmol) and 2-[5′-(2-hexyl-1,3-dioxolan-2-yl)-2,2′-bithien-5-yl]-4,4,5,5-tetramethyl-1,3,2-dioxaborolane (4.4 g, 9.8 mmol) in 60 ml of toluene, 10 ml of ethanol and an aqueous 2 M Na₂CO₃ solution (14 ml) were added to Pd(PPh₃)₄ (340 mg, 0.29 mmol) and the mixture was boiled under reflux for 12 hours. When the reaction was complete, 200 ml of toluene and 100 ml of water containing 29 ml of a 1N HCl solution were added. The organic phase was separated off, washed with water, dried over sodium sulphate and filtered. For purification, the crude product was chromatographed over silica gel (eluent: toluene), and was obtained as pale yellow crystals (yield: 2.32 g, 74%). ¹H NMR (250 MHz, CDCl₃): δ [ppm] 0.85 (t, 9H, J=6.7 Hz), 1.18-1.48 (overlapping signals, 24H), 2.00 (t, 6H, J=7.3 Hz), 3.93-4.08 (overlapping signals, 12H), 6.89 (d, 3H, J=3.7 Hz), 7.02 (d, 3H, J=3.7 Hz), 7.07-7.17 (overlapping signals, 12H), 7.48 (d, 6H, J=8.5 Hz). ¹³C NMR (125 MHz, CDCl₃): δ [ppm] 14.07, 22.56, 23.69, 29.27, 31.73, 40.57, 65.00, 109.01, 123.09, 123.11, 124.40, 124.44, 125.10, 126.50, 128.94, 136.11, 136.97, 142.65, 145.66, 146.40. Calculated (%) for C₆₉H₇₅NO₆S₆: C, 68.68; H, 6.26; N, 1.16; S, 15.94. Found: C, 68.89; H, 6.29; N, 1.08; S, 15.75.

### EXAMPLE 6

### 1,1′,1″-[Nitrilotris(4,1-phenylene-2,2′-bithiene-5′,5-diyl)]triheptan-1-one

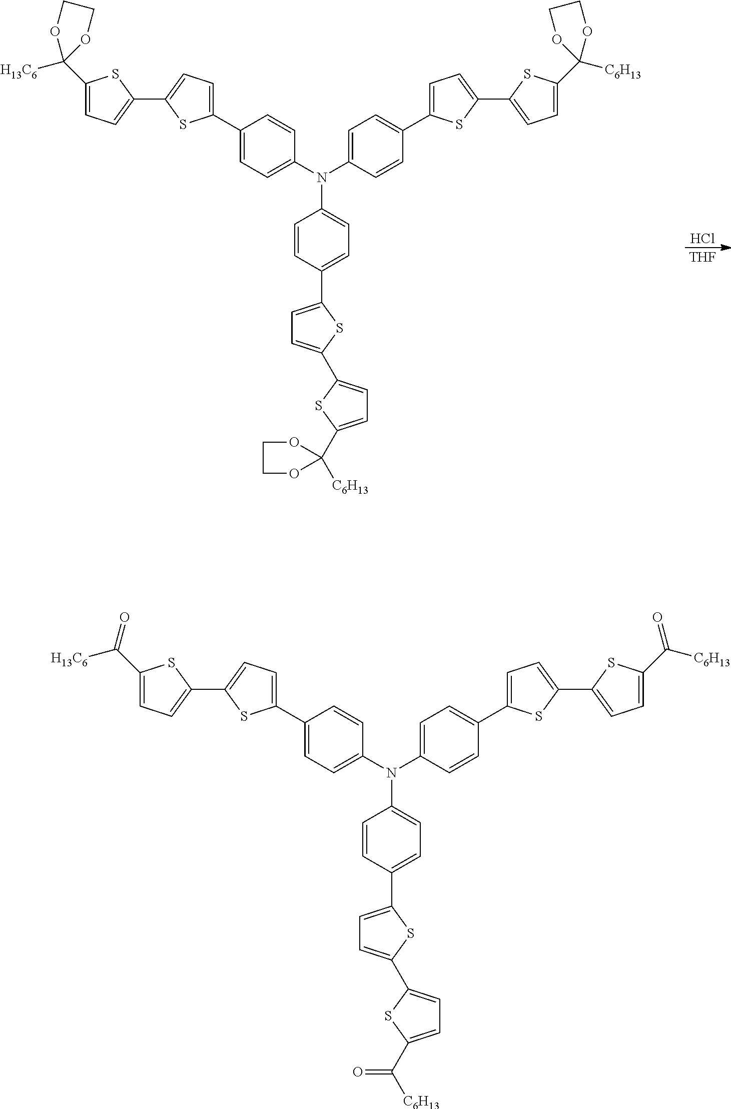

5.5 ml of a 1M HCl solution were added dropwise to a solution of tris {4-[5′-(2-hexyl-1,3-dioxolan-2-yl)-2,2′-bithien-5-yl]phenyl} amine (2.2 g, 1.8 mmol) in 70 ml of THF. After the solution had been stirred at room temperature for 2 hours, it was heated under reflux for a further 2 hours, the product partly precipitating as a yellow powder. When the reaction had ended, the organic phase was separated off and washed with water and the product was filtered off (yield: 1.52 g, 98%). ¹H NMR (250 MHz, CDCl₃): δ [ppm] 0.88 (t, 9H, J=6.1 Hz), 1.22-1.45 (overlapping signals, 18H), 1.74 (m, 6H, M=5, J=7.3 Hz), 2.86 (t, 6H, J=7.3 Hz) 7.11-7.18 (overlapping signals, 9H), 7.20 (d, 3H, J=3.7 Hz), 7.27 (d, 3H, J=3.7 Hz), 7.52 (d, 6H, J=8.5 Hz), 7.59 (d, 3H, J=4.3 Hz). Calculated (%) for C₆₃H₆₃NO₃S₆: C, 70.42; H, 5.91; N, 1.30; S, 17.90. Found: C, 71.10; H, 5.94; N, 1.19; S, 17.61.

### EXAMPLE 7

### 2,2′,2″-[Nitrilotris(4,1-phenylene-2,2′-bithiene-5′,5-diythept-1-yl-1-ylidene)]trimalononitrile

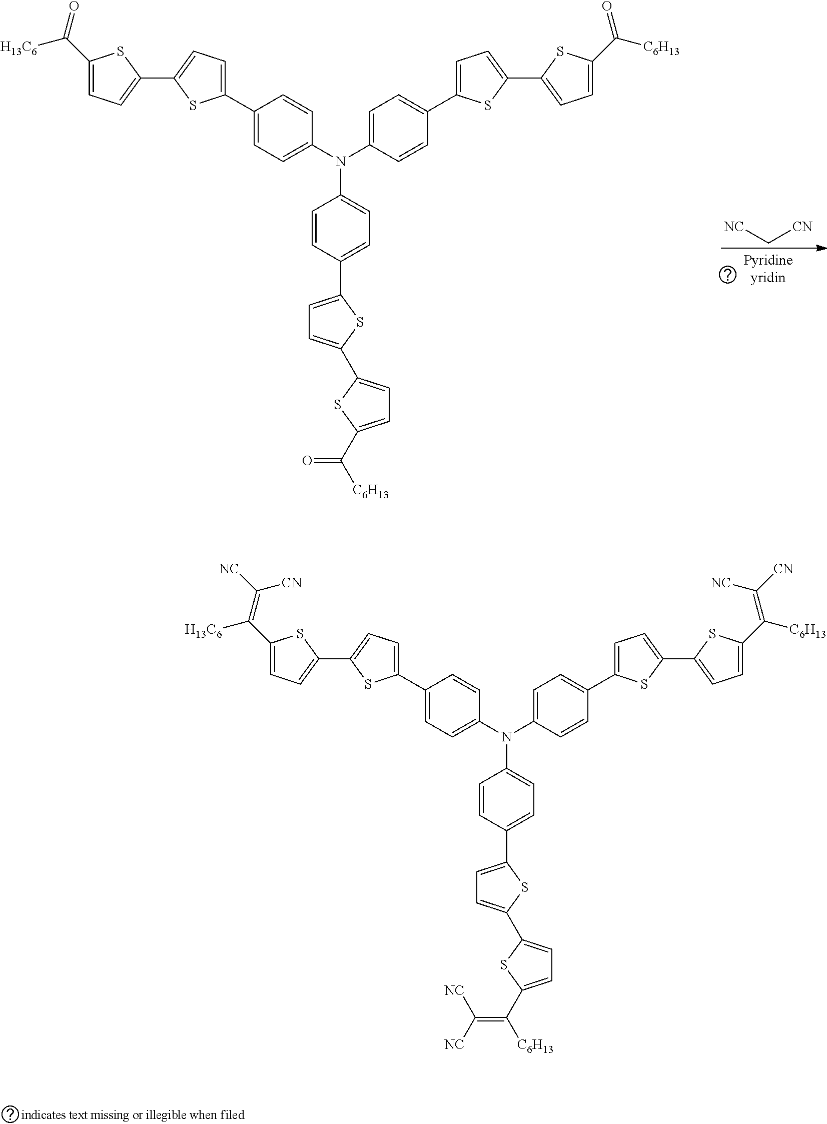

1,1′,1″-[Nitrilotris(4,1-phenylene-2,2′-bithiene-5′,5-diyl)] triheptan-1-one (1.78 g, 1.7 mmol), malonic acid dinitrile (1.31 g, 19.9 mmol) and anhydrous pyridine were stirred in a reaction vessel for 10 hours under microwave heating (105° C.). When the reaction was complete, the pyridine was removed in vacuo and the product was purified by chromatography with silica gel (eluent: toluene). 1.44 g (84%) of the pure product were obtained as a black powder. ¹H NMR (250 MHz, CDCl₃): δ [ppm] 0.89 (t, 9H, J=6.7 Hz), 1.20-1.50 (overlapping signals, 18H), 1.7 (m, 6H, M=5, J=7.3 Hz), 2.92 (t, 6H, J=7.3 Hz), 7.16 (d, 6H, J=8.5 Hz), 7.24 (d, 3H, J=3.7 Hz), 7.27 (d, 3H, J=4.3 Hz), 7.35 (d, 3H, J=3.7 Hz), 7.51 (d, 6H, J=8.5 Hz), 7.95 (d, 3H, J=4.3 Hz). ¹³C NMR (125 MHz, CDCl₃): δ [ppm] 13.97, 22.42, 29.19, 30.44, 31.26, 37.50, 113.87, 114.68, 123.83, 124.55, 124.78, 126.88, 127.64, 128.45, 133.76, 135.07, 135.15, 146.20, 146.72, 146.84, 166.32. Calculated (%) for C₇₂H₆₃N₇S₆: C, 70.96; H, 5.21; N, 8.04; S, 15.79. Found: C, 71.15; H, 5.31; N, 7.97; S, 15.52.

### EXAMPLE 8

### 2-[5-(2-Ethylhexyl)thien-2-yl]-4,4,5,5-tetramethyl-1,3,2-dioxaborolane (EH-T-BPin)

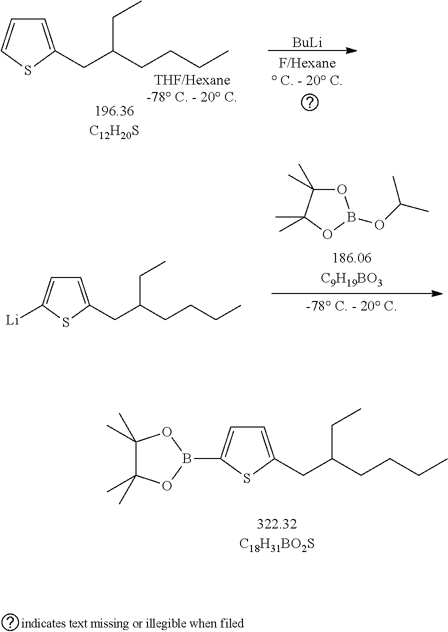

41 ml of n-butyllithium (2.5 M in hexane) were added at −78° C. to 150 ml of THF. Thereafter, a solution of 20 g of EH-T in 150 ml of THF was added at −65° C. in the course of 30 minutes and the mixture was stirred at −78° C. for 1 h. After warming to 0° C., the mixture was cooled again to −65° C., 21 ml of 2-isopropoxy-4,4,5,5-tetramethyl-1,3,2-dioxaborolane were added all at once and the mixture was stirred in the cold for 20 min and at room temperature overnight. The cloudy solution was stirred into 600 ml of MTBE and the resulting mixture was added to a solution of 900 ml of ice-water with 100 ml of HCl (1M). After separation of the phases, the organic phase was washed with 2×500 ml of water and dried over sodium sulphate and the solvent was removed on a rotary evaporatot. Yield: 0.58 g (93%) of a pale pink clear oil; ¹H NMR (400 MHz, CDCl₃) δ 7.47 (d, J=3.4 Hz, 1H), 6.84 (d, J=3.4 Hz, 1H), 2.79 (d, J=6.9 Hz, 2H), 1.64-1.56 (m, 1H), 1.37-1.24 (m, 20H), 0.88 (dd, J=8.4, 6.4 Hz, 6H).

### EXAMPLE 9

### 2-{2-[5-(2-Ethylhexyl)-thien-2-yl]-thien-5-yl}-7-(thien-2-yl)-2,1,3-benzothia-diazole (EH-2T-BTD-T)

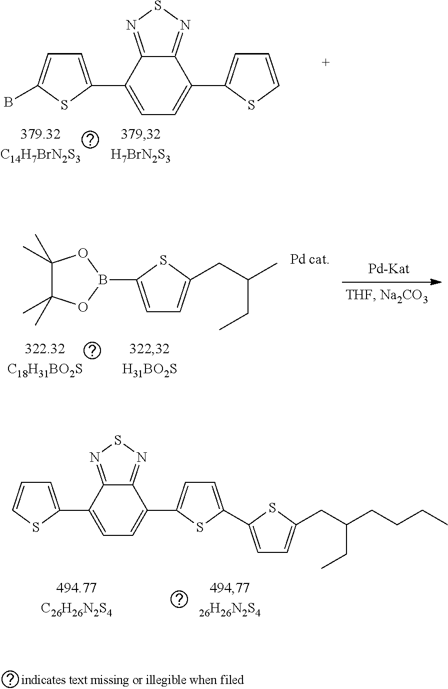

350 mg of tetrakis(triphenylphosphine)palladium(0) and 25 ml of degassed 2 M sodium carbonate solution were added to a degassed solution of 7.33 g of Br-T-BTD-T and 6.00 g of EHT-BPin in 110 ml of tetrahydrofuran and the mixture was stirred at 60° C. for 22 h. Thereafter, a further 2 g of EH-T-BPin and 150 mg of tetrakis(triphenylphosphine)palladium(0) were added and stirring was continued until the conversion was complete. The reaction mixture was added to 260 ml of ice-cooled hydrochloric acid (0.1M), while stirring, and the mixture was stirred for 15 min. It was extracted by shaking with 5×100 ml of toluene. The combined organic phases were washed with 2×100 ml of water, dried over sodium sulphate and concentrated on a rotary evaporator and the residue was dried. The substance was purified by chromatography (mobile phase: hexane/toluene 4/1). 4.0 g (70%) of a red solid were obtained. ¹H NMR (400 MHz, CDCl₃) δ 8.12 (dd, J=3.6, 1.1 Hz, 1H), 8.03 (d, J=3.9 Hz, 1H), 7.85 (q, J=7.6 Hz, 2H), 7.46 (dd, J=5.2, 1.0 Hz, 1H), 7.21 (dd, J=5.0, 3.8 Hz, 1H), 7.19 (d, J=3.9 Hz, 1H), 7.11 (d, J=3.5 Hz, 1H), 6.71 (d, J=3.5 Hz, 1H), 2.76 (d, J=6.8 Hz, 2H), 1.61 (dt, J=11.9, 6.0 Hz, 1H), 1.44-1.23 (m, 8H), 0.91 (t, J=7.4 Hz, 6H).

### EXAMPLE 10

### 2-(2-Bromothien-5-yl)-7-{2-[5-(2-ethylhexyl)-thien-2-yl]-thien-5-yl}-2,1,3-benzothiadiazole (EH-2T-BTD-T-Br)

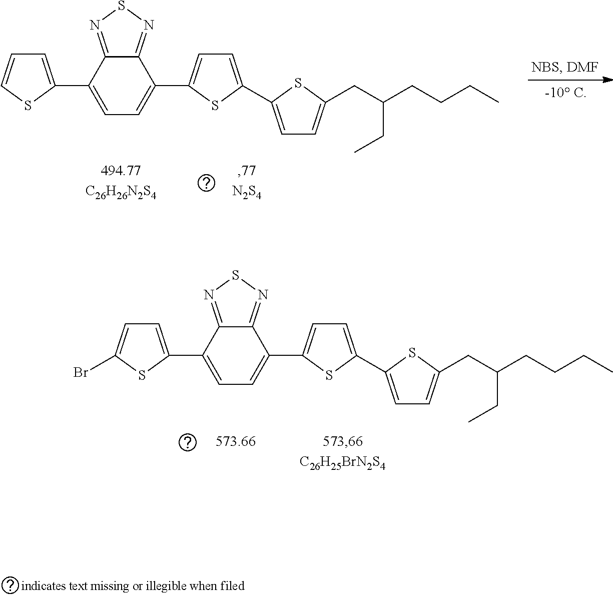 [SMILES: CCCCC(CC)Cc1ccc(-c2ccc(-c3ccc(-c4cccs4)c4nsnc34)s2)s1 ; CCCCC(CC)Cc1ccc(-c2ccc(-c3ccc(-c4ccc(Br)s4)c4nsnc34)s2)s1]

A solution of 2.67 g of N-bromosuccinimide in 200 ml of anhydrous DMF was added dropwise at 0° C. to a solution, kept in the dark, of 6 g of EH-2T-BTD-T in 200 ml of anhydrous

DMF in the course of 95 min and the mixture was stirred at RT overnight. A further 0.52 g (0.5 eq) of N-bromosuccinimide was subsequently added in small portions and the mixture was stirred for a further hour. The solution was stirred into 800 ml of ice-water with evolution of heat and the mixture was subsequently stirred for 20 min. The red suspension was extracted with 3×250 ml of toluene. The combined toluene phases were washed with 2×250 ml of water, dried over sodium sulphate and concentrated on a rotary evaporator and the Bordeaux red solid was dried. Yield: 3.52 g, (48%). ¹H NMR (400 MHz, CDCl₃) δ 8.04 (d, J=3.9 Hz, 1H), 7.83 (d, J=7.6 Hz, 1H), 7.80 (d, J=2.9 Hz, 1H), 7.79 (d, J=7.7 Hz, 1H), 7.19 (d, J=3.9 Hz, 1H), 7.15 (d, J=3.9 Hz, 1H), 7.11 (d, J=3.5 Hz, 1H), 6.71 (d, J=3.5 Hz, 1H), 2.76 (d, J=6.7 Hz, 2H), 1.65-1.57 (m, 1H), 1.43-1.27 (m, 98H), 0.95-0.88 (m, J=9.1, 5.7 Hz, 6H).

### EXAMPLE 11

### 2-[2-(4,4,5,5,-tetramethyl-1,3,2-dioxaborolan-2-yl-thien-5-yl]-7-{2-[5-(2-ethylhexyl)thien-2-yl]-thien-5-yl}-2,1,3-benzothiadiazole (EH-2T-BTD-T-BPin)

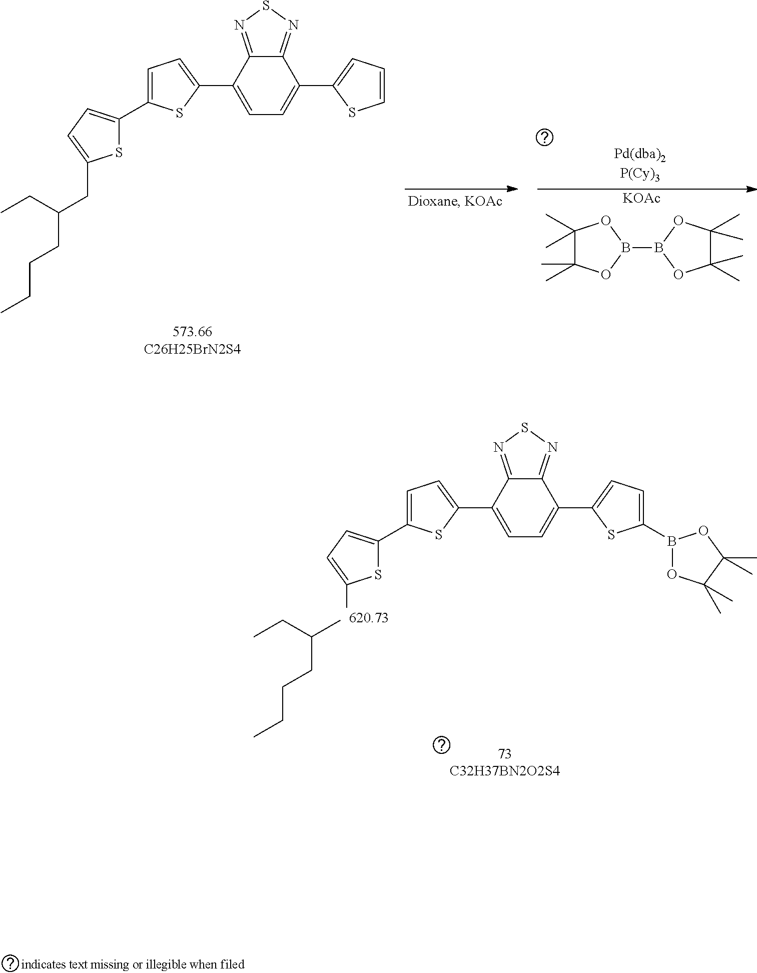

Bis(dibenzylideneacetone)palladium, tricyclohexylphosphine, EH-2T-BTD-T-Br, 4,4,4′,4′,5,5,5′,5′-octamethyl-2,2′-bi(1,3,2-dioxaborolane) and potassium acetate were dried in a vacuum drying cabinet at 40° C. for 6 h. A suspension of 0.32 g of tricyclohexylphosphine and 0.28 g of bis(dibenzylideneacetone)palladium in 60 ml of dioxane was stirred for 30 min. 6.08 g of EH-2T-BTD-T-Br in 25 ml of dioxane were subsequently added. Thereafter, 2.97 g of 4,4,4′,4′,5,5,5′,5′-octamethyl-2,2′-bi(1,3,2-dioxaborolane) and finally 1.6 g of potassium acetate were added. The reaction mixture was heated at 80° C. for 4 h. The solution was stirred into 250 ml of water and the suspension obtained was extracted with 4×120 ml of toluene. The combined organic phases were washed with 2×100 ml of water and 100 ml of saturated aqueous sodium chloride solution, dried over sodium sulphate and concentrated on a rotary evaporator. The dark red residue was taken up again in chloroform, adsorbed on silica gel and filtered over silica gel with 5 1 of methanol. Yield: 2.2 g (34%) of a dark red filmy solid. ¹H NMR (400 MHz, CDCl₃) δ 8.18 (d, J=3.8 Hz, 1H), 8.05 (d, J=3.9 Hz, 1H), 7.93 (d, J=7.7 Hz, 1H), 7.85 (d, J=7.7 Hz, 1H), 7.71 (d, J=3.8 Hz, 1H), 7.20 (d, J=3.9 Hz, 1H), 7.12 (d, J=3.5 Hz, 1H), 6.71 (d, J=3.5 Hz, 1H), 2.76 (d, J=6.7 Hz, 2H), 1.92 (m, 1H), 1.38 (s, 12H), 1.40-1.24 (m, 8H), 0.97-0.85 (m, 6H).

### EXAMPLE 12

### 1,3,5{4-(4,4,5,5-Tetramethyl-[1,3,2]dioxaborolane)phenyl}benzene

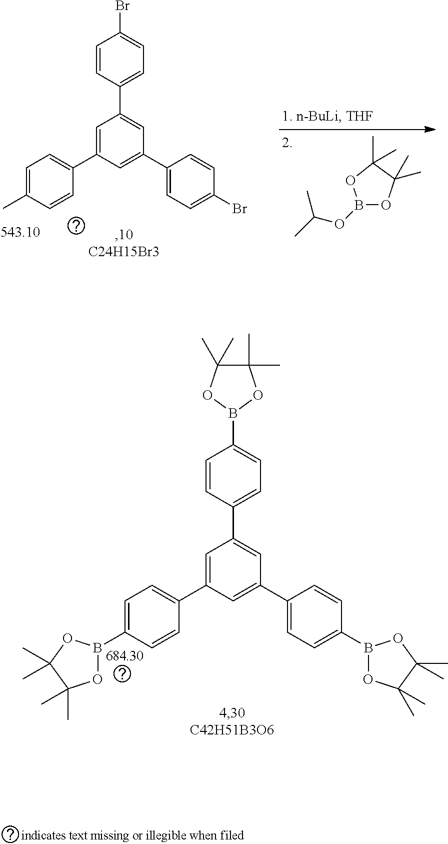

2.4 ml of n-butyllithium (2 M in hexane) were added at −80° C. to a solution of 1.09 g of 1,3,5-(4-bromophenyl)benzene in 40 ml of THF. The mixture was stirred at −80° C. for 1 h and 1.3 ml of 2-isopropoxy-4,4,5,5-tetramethyl-[1,3,2]dioxaborolane were subsequently added to the resulting suspension. After warming to room temperature, the solvent was removed. The residue was suspended in chloroform and subsequently suspended in water. After separation of the phases, the aqueous phase was extracted with chloroform. The combined chloroform phases were dried over sodium sulphate and concentrated to 2 ml on a rotary evaporator. 10 ml of hot ethanol were added to the residue and the mixture was recrystallized at 24° C. overnight. The product obtained was filtered off with suction and dried in vacuo.

The compounds according to the invention can also be prepared in an analogous manner starting from the following branching groups K present as an organoboron compound:

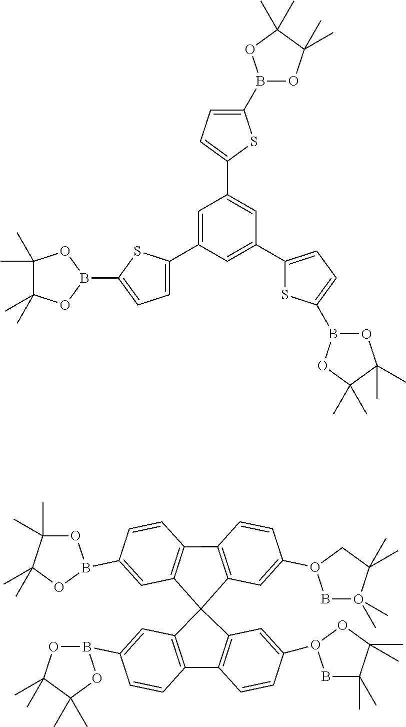

### EXAMPLE 13

Tris-4-{2-[2-(2-[5-(2-ethythexyl)-thien-2-yl]-thien-5-yl)-2,1,3-benzothiadiazol-7-yl]-thien-5-yl}-phenylamine

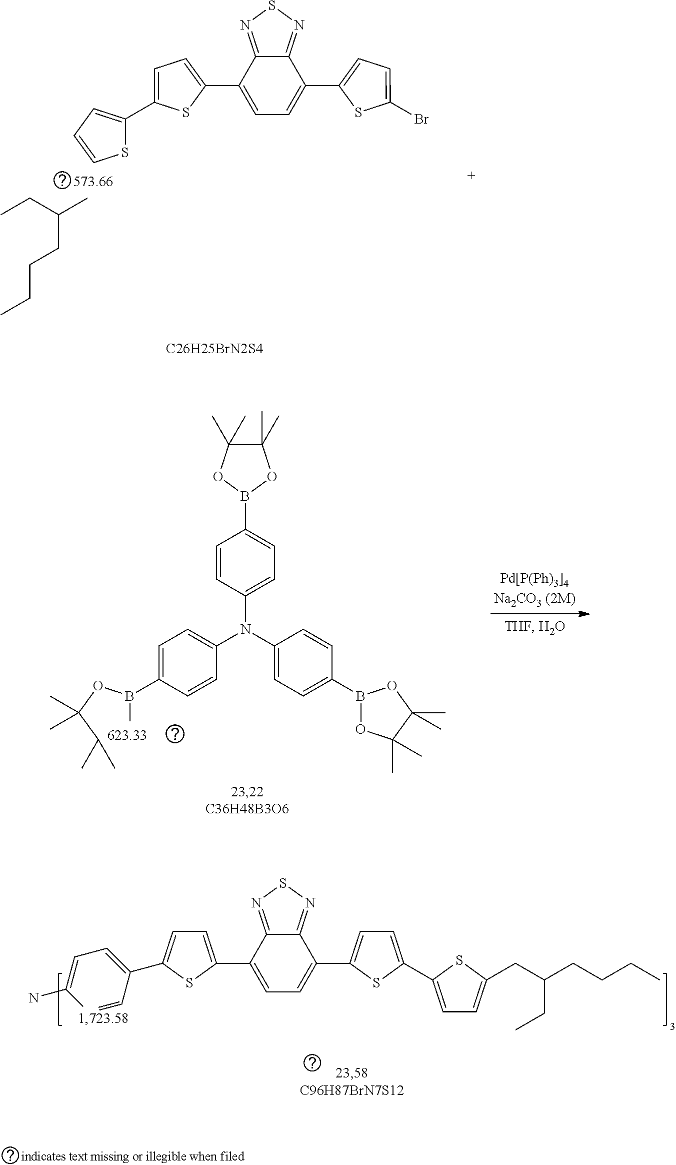

140 mg of tetrakis(triphenylphosphine)palladium(0) and subsequently 3 ml of degassed sodium carbonate solution (2 M) were added to a degassed solution of 1.38 g of EH-2T-BTD-T-Br in 60 ml of THF and the mixture was heated to 60° C. A solution of 0.50 g of tris {4-(4,4,5,5-tetramethyl-[1,3,2]dioxaborolane)phenyl} amine in 40 ml of THF was added dropwise in the course of 1 h and the mixture was stirred at 60° C. until the end of the reaction (TLC control). Thereafter, the reaction mixture was added to 200 ml of water and 6 ml of hydrochloric acid (1M) were added, and the mixture was stirred for a further 10 min. The mixture was extracted with 3×100 ml of chloroform. The combined organic phases were washed with 100 ml of water, dried over sodium sulphate and concentrated on a rotary evaporator. The crude product was separated by means of gradient column chromatography (mobile phase: hexane/toluene 3/1, toluene and methanol).

The following compounds according to the invention can be prepared in an analogous manner:

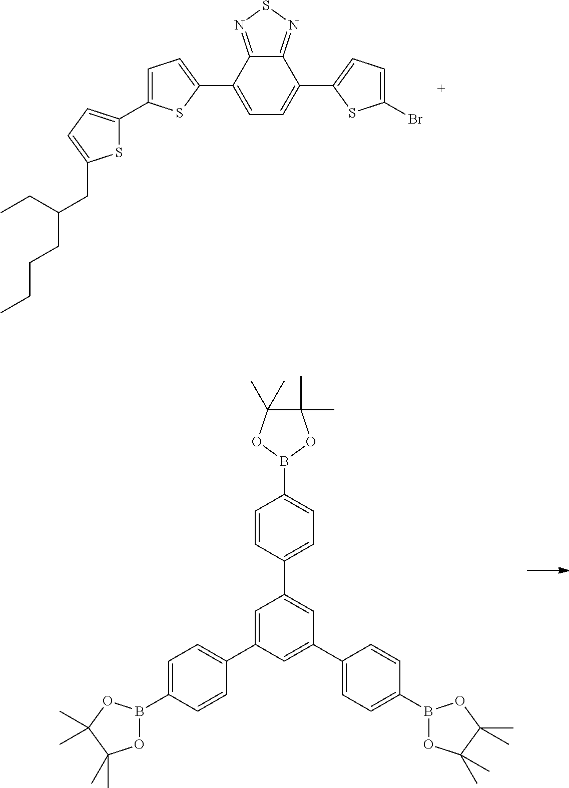

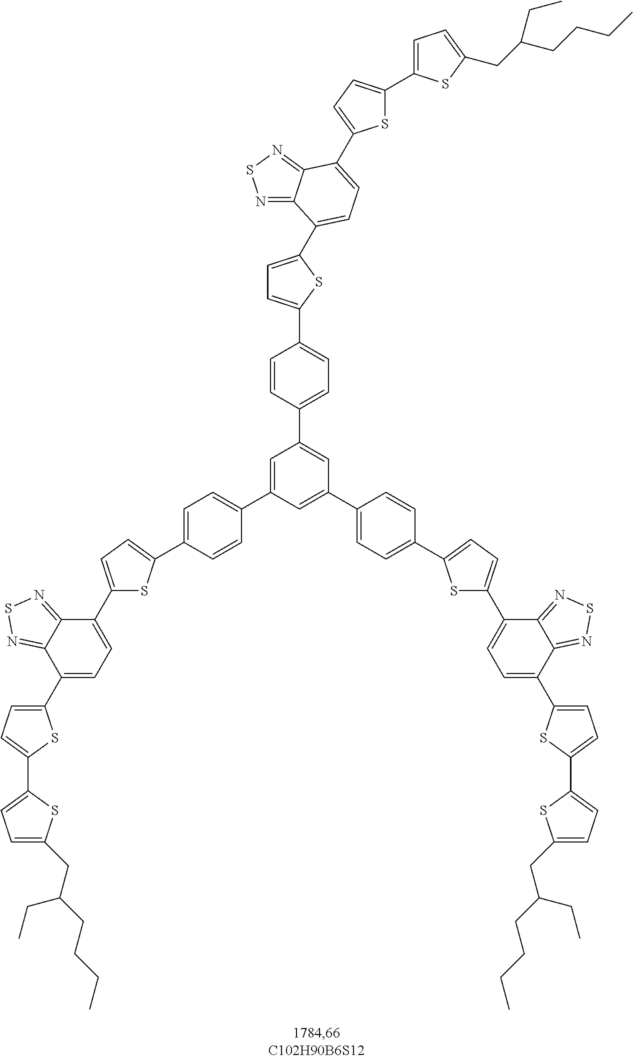 [SMILES: CCCCC(CC)Cc1ccc(-c2ccc(-c3ccc(-c4ccc(-c5ccc(-c6cc(-c7ccc(-c8ccc(-c9ccc(-c%10ccc(-c%11ccc(CC(CC)CCCC)s%11)s%10)c%10nsnc9%10)s8)cc7)cc(-c7ccc(-c8ccc(-c9ccc(-c%10ccc(-c%11ccc(CC(CC)CCCC)s%11)s%10)c%10nsnc9%10)s8)cc7)c6)cc5)s4)c4nsnc34)s2)s1]

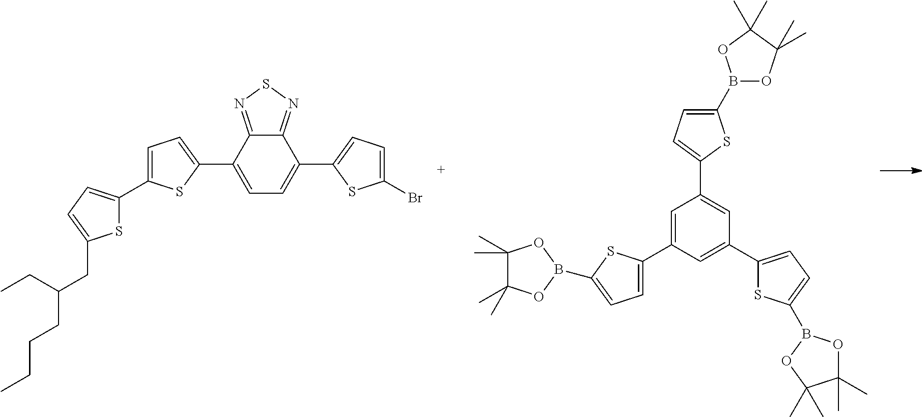

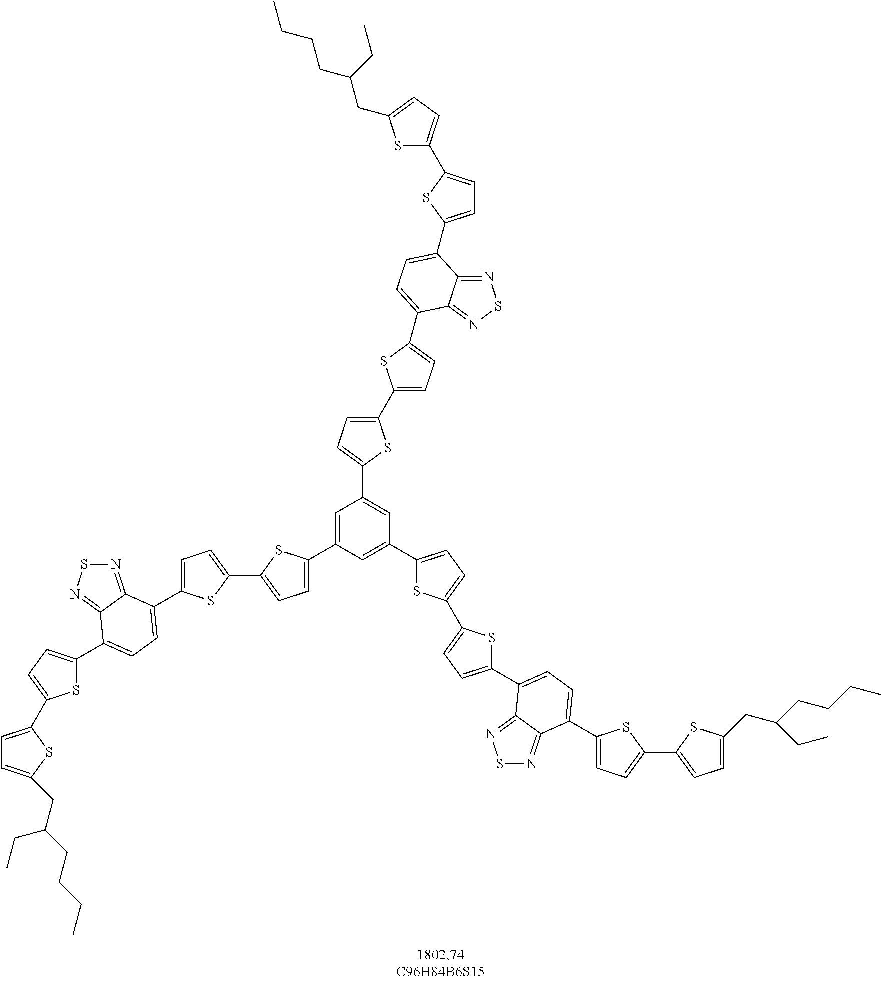 [SMILES: CCCCC(CC)Cc1ccc(-c2ccc(-c3ccc(-c4ccc(-c5ccc(-c6cc(-c7ccc(-c8ccc(-c9ccc(-c%10ccc(-c%11ccc(CC(CC)CCCC)s%11)s%10)c%10nsnc9%10)s8)s7)cc(-c7ccc(-c8ccc(-c9ccc(-c%10ccc(-c%11ccc(CC(CC)CCCC)s%11)s%10)c%10nsnc9%10)s8)s7)c6)s5)s4)c4nsnc34)s2)s1]

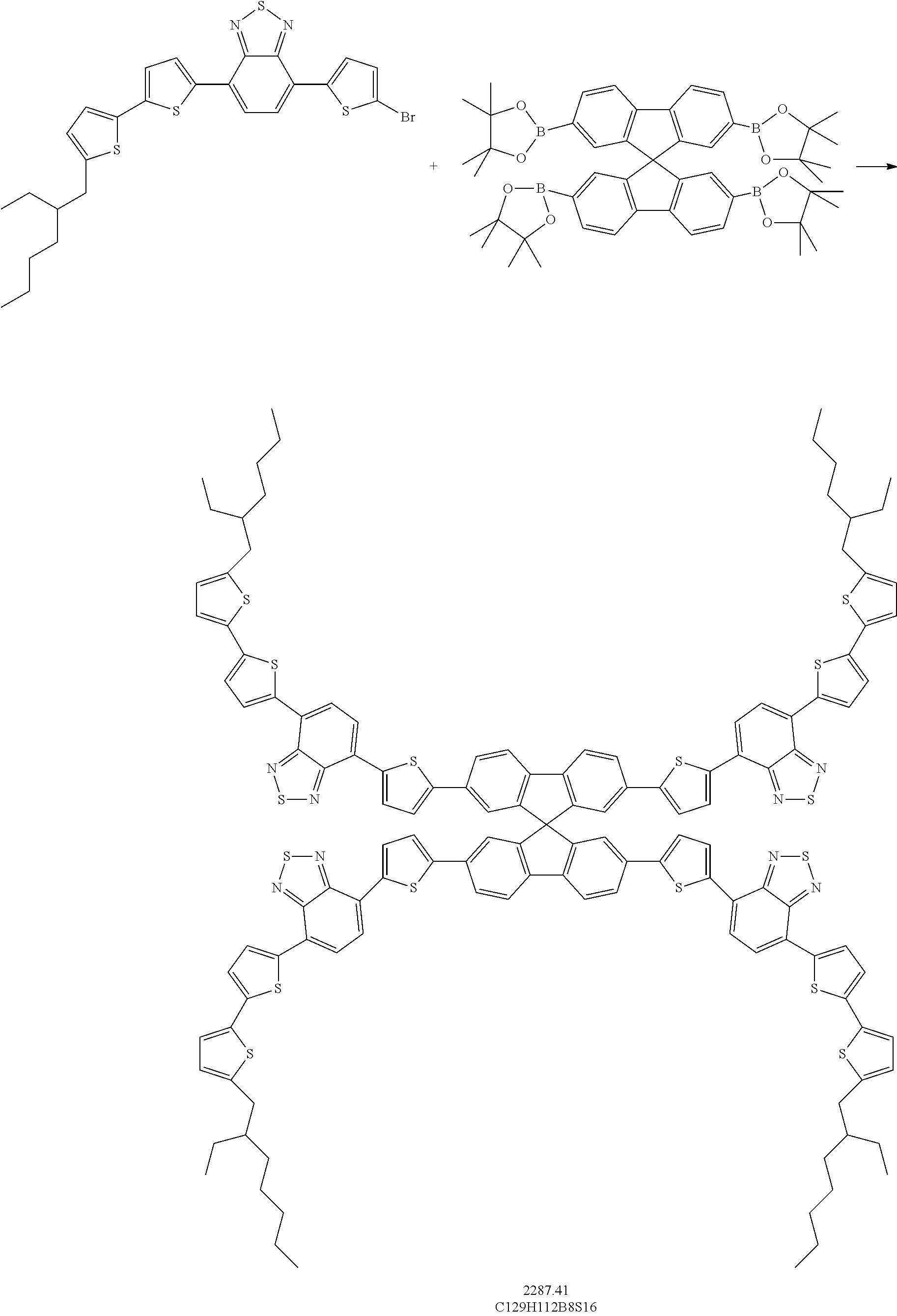

### EXAMPLE 14

The compound according to the invention from Example 7 is used for construction of an organic solar cell (OSC). The procedure for the production of the OSCs is as follows:

### 1. Preparation of the ITO-Coated Substrate

ITO-coated glass (Merck Balzers AG, FL, part no. 253 674 XO) is cut into pieces 25 mm×25 mm in size (substrates). The substrates are then cleaned in 3% aqueous Mucasol solution in an ultrasound bath for 15 min. Thereafter, the substrates are rinsed with distilled water and spin-dried in a centrifuge. Immediately before coating, the ITO-coated sides are cleaned for 10 min in a UV/ozone reactor (PR-100, UVP Inc., Cambridge, GB).

### 2. Application of the Hole-Extracting Layer (HEL)

About 10 ml of the aqueous solution of CLEVIOS™ P AI4083 (Heraeus Clevios GmbH, Leverkusen) are filtered (Millipore HV, 0.45 μm). The cleaned ITO-coated substrate is laid on a spincoater and the filtered solution is distributed on the ITO-coated side of the substrate. The excess solution is then removed by rotating the plate at 800 rpm over a period of 30 s. Thereafter, the substrate coated in this way is dried on a hot-plate at 200° C. for 5 min. The layer thickness is 60 nm (Dektac 150, Veeco).

The substrate coated with the HEL is transferred into a glove box system (M. Braun). All the following steps 3-5 are carried out here under a nitrogen atmosphere under a partial pressure of water and oxygen of less than 1 ppm.

### 3. Application of the Light-Absorbing Layer (LAL)

46.7 mg of the compound according to the invention from Example 7 and 46.6 mg of the substance [6,6]-phenyl-C61-butyric acid methyl ester-1-[3-(methoxycarbonyl)propyl]-1-phenyl-[6.6]C61-3′H-cyclopropa[1,9] [5,6] fullerene-C60-Ih-3′-butyric acid 3′-phenylmethyl ester (PCBM, Solenne B.V., batch 25-02-10) are stirred in 3.02 ml of dichlorobenzene on a hot-plate at approx. 50° C. until all the material has dissolved completely. The solution is then filtered in the hot state via a syringe filter (Millipore HV, 0.45 μm) and then distributed on the HEL-coated substrate, which is on a spincoater. The excess solution is removed by rotating the plate at 500 rpm over a period of 30 s. Thereafter, the substrate coated in this way is dried on a hot-plate at 60° C. for 10 min. The total layer thickness of HEL and LAL is 145 nm (Dektac 150, Veeco).

### 4. Application of the Metal Cathode

Metal electrodes are vapour-deposited as cathodes on the substrate with the ITO//HEL//LAL layer system. A vacuum apparatus (Edwards) equipped with two thermal vaporizers which is integrated into the glove box system is used for this. The layer system is covered with a shadow mask which consists of circular holes of 2.5 mm and 6 mm diameter. The substrate is laid on the rotating sample holder with the mounted shadow mask downwards. The dimensions of the sample holder are such that four substrates can be accommodated at the same time. A 25 nm thick Ca layer and then, without intermediate ventilation, an 80 nm thick Ag layer are vapour-deposited from two thermal vaporizers under a pressure of p=10⁻³ Pa. The vapour deposition rates are 10 Å/s for Ba and 20 Å/s for Ag. The circular metal electrodes isolated from one another have an area of 4.9 mm² and 28 mm² respectively.

### 5. Characterization of the OSC

The characterization of the OSC is likewise carried out in the glove box system filled only with nitrogen. A solar simulator (1,000 W quartz-halogen-tungsten lamp, Atlas Solar Celltest 575), the homogeneous light of which is directed upwards, is recessed into the base of this. An aluminium plate with a circular recess of 2 cm diameter as a holder for the OSC is located in the cone of light. The OSC to be measured is positioned centrally over the recess. The distance from the sample plane to the base is 10 cm. The light intensity can be attenuated with inserted grating filters. The intensity at the sample plane is measured with an Si photocell and is approx. 500 W/m². The Si photocell was calibrated beforehand with a pyranometer (CM10). The temperature of the sample holder is determined with a heat sensor (PT100+testtherm 9010) and is max. 40° C. during the measurement.

The OSC is contacted electrically by connecting the ITO electrode to an Au contact pin (+ pole) and pressing a thin flexible Au wire on to one of the metal electrodes (− pole). Both contacts are connected via a cable to a current/voltage source (Keithley 2800). The light source is first covered and the current/voltage characteristic line is measured. For this, the voltage is increased from −1 V to +1 V in increments of 0.01 V and then lowered again to −1 V. The current is recorded at the same time. Thereafter, the characteristic line is plotted analogously under illumination. From these data, the parameters relevant to the solar cell, such as conversion efficiency (efficiency TO, open circuit voltage (OCV), short circuit current (SCC) and fill factor (FF), are determined in accordance with the European standard EN 60904-3.

### 6. Results:

In a current/voltage characteristic line of the cell construction described in Example 1-5, on the left is plotted the current density over the voltage, and on the right the electrical power of the photocell over the voltage applied. The maximum of the curve gives the highest power of the cell (Pm) at a radiation power of P0=498 W/m² and specifies the maximum power voltage (WP). The efficiency rl and the fill factor FF can be calculated according to η=Pm/P0 and FF=Pm/(OCV·SCC). These parameters are shown in Table 1.

### EXAMPLE 15

The compound according to the invention from Example 7 is used for construction of an organic solar cell (OSC). The procedure for the production of the OSCs is as in Example A, with the difference that under point 3. “Application of the light-absorbing layer (LAL)” 48.8 mg of the compound according to the invention from Example 7 and 97.6 mg of the fullerene PCBM (Solenne B.V., batch 25-02-10) are dissolved in 4.73 ml of dichlorobenzene. The layer is produced analogously to Example A point 3. The total layer thickness of HEL and LAL is 140 nm (Dektac 150, Veeco).

The OSC-relevant parameters are shown in Table 1.

### EXAMPLE 16

### Comparison Example

The procedure for the production of the comparison cells is as in Example 14, with the difference that under point 3. “Application of the light-absorbing layer (LAL)” 97.8 mg of the substance poly(3-hexylthiophene-2,5-diyl) (P3HT, Sepiolid P 200, BASF) are stirred with 97.9 mg of the fullerene PCBM (Solenne B.V., batch 25-02-10) in 6.33 ml of dichlorobenzene on a hot-plate at approx. 50° C. until all the material has dissolved completely. The solution is then filtered in the hot state over a syringe filter (Millipore HV, 0.45 pm) and then distributed on the HEL-coated substrate, which is on a lacquer whirler coater. The excess solution is spun off by rotating the plate at 750 rpm over a period of 30 s. Thereafter, the substrate coated in this way is dried on a hot-plate at 130° C. for 10 min. The total layer thickness of HEL and LAL is 210 nm (Dektac 150, Veeco).

The OSC-relevant parameters are shown in Table 1.

### EXAMPLE 17

### Comparison Example

The procedure for the production of the comparison cells is as in Example 14, with the difference that under point 3. “Application of the light-absorbing layer (LAL)” 72.8 mg of the substance poly(3-hexylthiophene-2,5-diyl) (P3HT, Sepiolid P 200, BASF) are stirred with 145.6 mg of the fullerene PCBM (Solenne B.V., batch 25-02-10) in 7.06 ml of dichlorobenzene on a hot-plate at approx. 50° C. until all the material has dissolved completely. The solution is then filtered in the hot state via a syringe filter (Millipore HV, 0.45 μm) and then distributed on the HEL-coated substrate, which is on a spincoater. The excess solution is spun off by rotating the plate at 750 rpm over a period of 30 s. Thereafter, the substrate coated in this way is dried on a hot-plate at 130° C. for 10 min. The total layer thickness of HEL and LAL is 210 nm (Dektac 150, Veeco).

The OSC-relevant parameters are shown in Table 1.

### CONCLUSION EXAMPLES 14-17

As can be seen from Table 1, the compound according to the invention from Example 7 is suitable as a component for the construction of the active layer of OSCs deposited from solution. Compared with the prior art, such as e.g. P3HT:PCBM, the compound according to the invention from Example 7 has the advantage of higher open circuit voltages (OCV). As can be seen from Table 1, the open circuit voltage for cells comprising the compound according to the invention from Example 7 in combination with PCBM is 0.85 V -0.9 V, whereas with the comparison substance in similarly processed cells only 0.54 V -0.56 V is reached.

TABLE 1

| | Compound | | | | | | | |
|---|---|---|---|---|---|---|---|---|
| | from | | | | | | | |
| | Example 7: | Area | SCC | OCV | Pm | P0 | η | |
| | PCBM | [cm²] | [mA/cm²] | [V] | [mW/cm²] | [W/m²] | [%] | FF |
| Ex. 14 | 1:1 | 0.283 | 2.06 | 0.890 | 0.68 | 498 | 1.37 | 0.37 |
| | 1:1 | 0.049 | 2.24 | 0.876 | 0.75 | 498 | 1.51 | 0.38 |
| | 1:1 | 0.049 | 1.96 | 0.873 | 0.56 | 498 | 1.12 | 0.32 |
| | 1:1 | 0.049 | 2.13 | 0.702 | 0.56 | 498 | 1.12 | 0.37 |
| Ex. 15 | 1:2 | 0.283 | 2.38 | 0.777 | 0.67 | 498 | 1.34 | 0.36 |
| | 1:2 | 0.049 | 2.25 | 0.865 | 0.76 | 498 | 1.53 | 0.39 |
| | 1:2 | 0.283 | 1.75 | 0.843 | 0.56 | 498 | 1.13 | 0.38 |
| | 1:2 | 0.049 | 1.66 | 0.755 | 0.48 | 498 | 0.97 | 0.38 |
| | P3HT: | Area | SCC | OCV | Pm | P0 | η | |
| | PCBM | [cm²] | [mA/cm²] | [V] | [mW/cm²] | [W/m²] | [%] | FF |
| Ex. 16 | 1:1 | 0.049 | 2.87 | 0.556 | 0.97 | 488 | 1.99 | 0.61 |
| | 1:1 | 0.282 | 3.57 | 0.560 | 1.02 | 488 | 2.08 | 0.51 |
| | 1:1 | 0.049 | 3.57 | 0.559 | 1.19 | 488 | 2.44 | 0.60 |
| | 1:1 | 0.049 | 3.73 | 0.551 | 1.24 | 488 | 2.54 | 0.60 |
| | 1:1 | 0.282 | 3.48 | 0.559 | 0.90 | 488 | 1.84 | 0.46 |
| Ex. 17 | 1:2 | 0.282 | 1.77 | 0.551 | 0.53 | 485 | 1.10 | 0.55 |
| | 1:2 | 0.049 | 1.64 | 0.540 | 0.43 | 485 | 0.89 | 0.49 |
| | 1:2 | 0.049 | 1.95 | 0.550 | 0.60 | 485 | 1.25 | 0.57 |
| | 1:2 | 0.282 | 1.80 | 0.549 | 0.51 | 485 | 1.05 | 0.51 |

1. Compounds of the general formula (I) 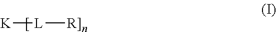
wherein
n is an integer from 3 to 6,
R represents H or a non-conjugated chain,
L are linear conjugated units according to the general formula (II) 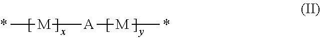
in which
x, y in each case independently of each other represent an integer from 0 to 20,
A represents an acceptor group according to one of the following formulae IIIa-IIIr 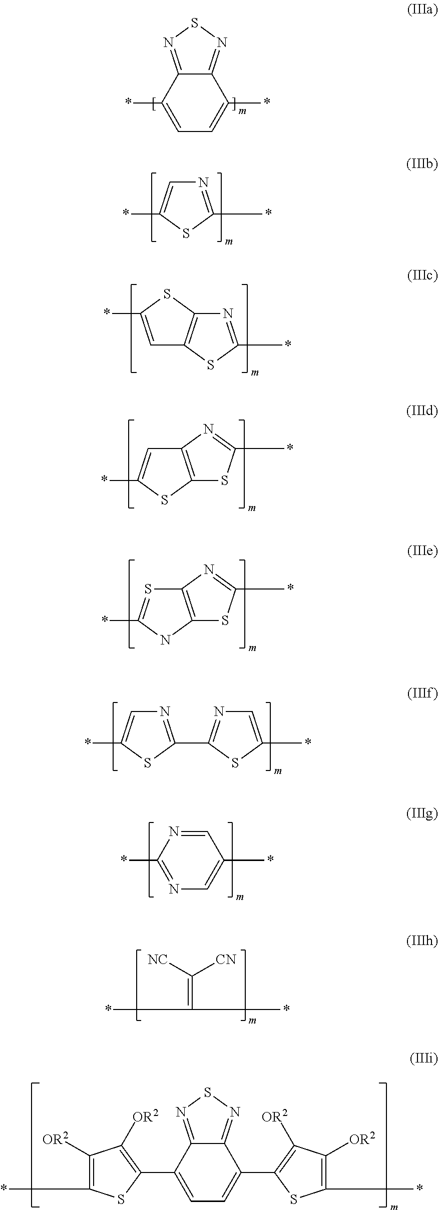 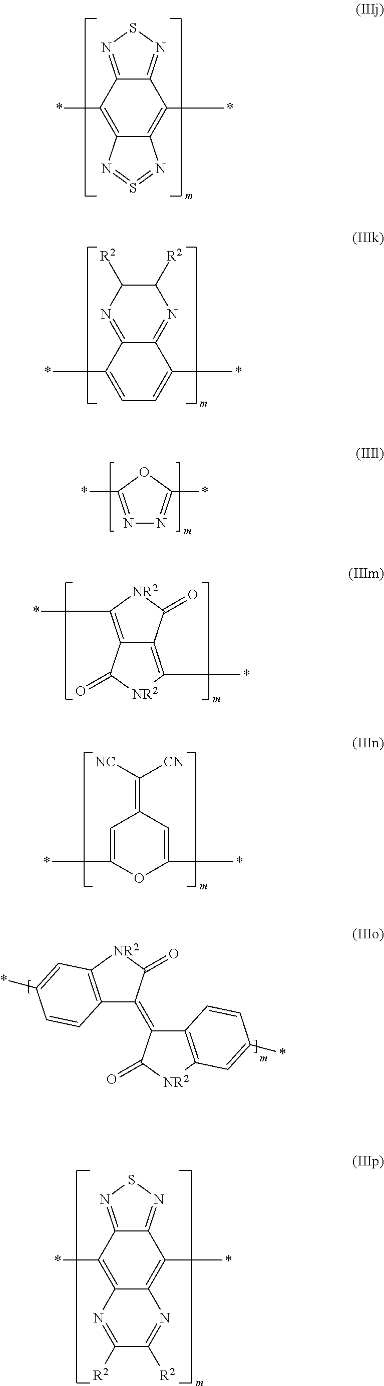 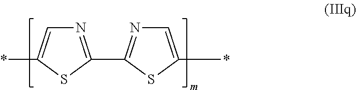
in which
m represents an integer from 1 to 20,
R² represents H or a linear or branched C₁-C₂₀-alkyl group, preferably a C₁-C₁₂-alkyl group, a linear C₁-C₂₀-alkyl group, preferably C₁-C₁₂-alkyl group, which is optionally interrupted by one or more O or S atoms or silylene, phosphonoyl or phosphoryl groups, or an optionally substituted aromatic radical,
in the case of the acceptor group IIIh R≠H,
M represents an aryl compound according to one of the following formulae IVa-IVr 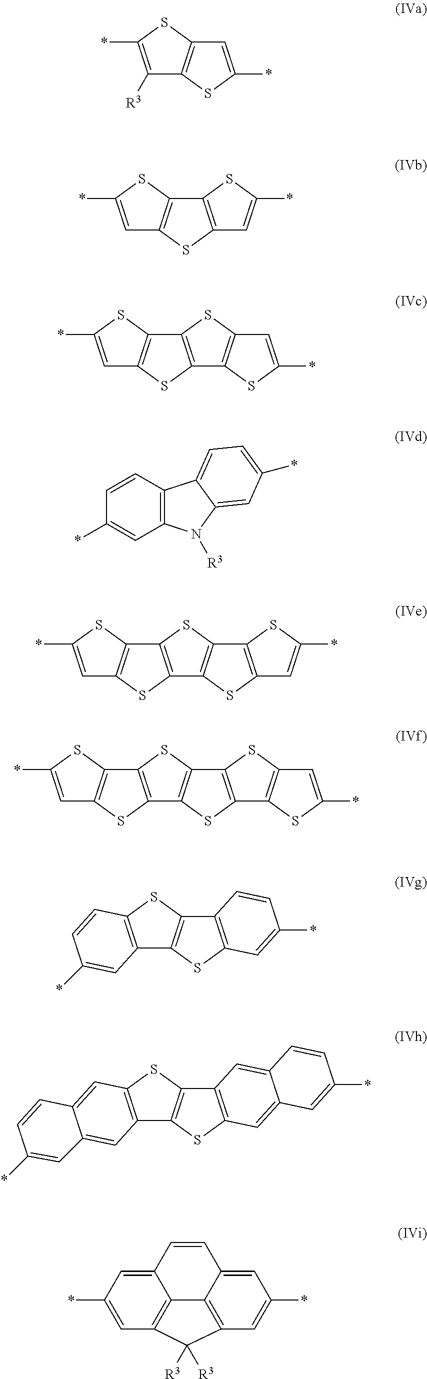 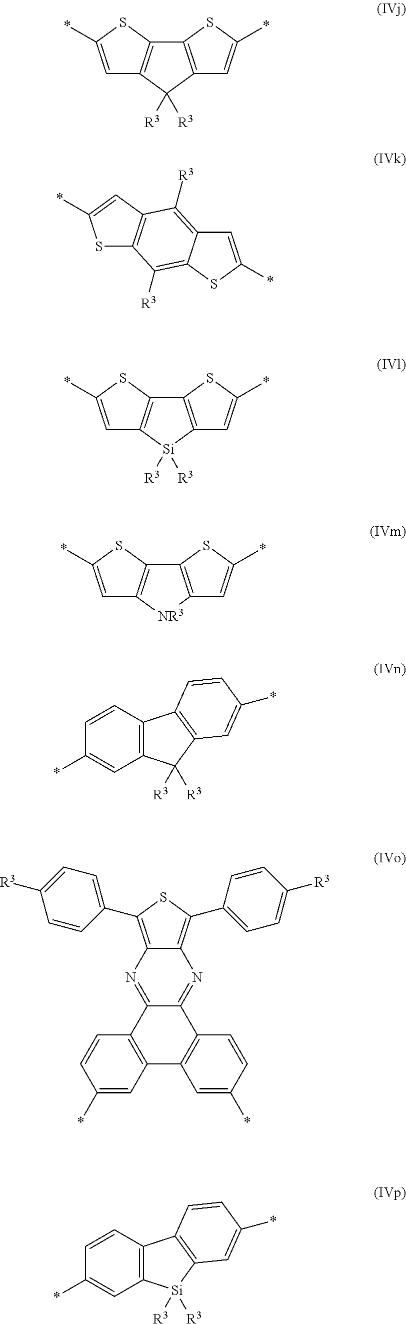 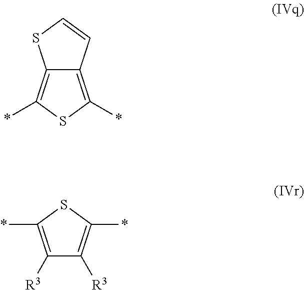
in which
R³ represents H or a linear or branched C₁-C₂₀-alkyl group, preferably a C₁-C₁₂-alkyl group, or a linear C₁-C₂₀-alkyl group, preferably C₁-C₁₂-alkyl group, which is optionally interrupted by one or more O or S atoms or silylene, phosphonoyl or phosphoryl groups, where, if the aryl compound A comprises two radicals R³, these can be identical or different,
K represents a branching group according to one of the following formulae Va-Vt 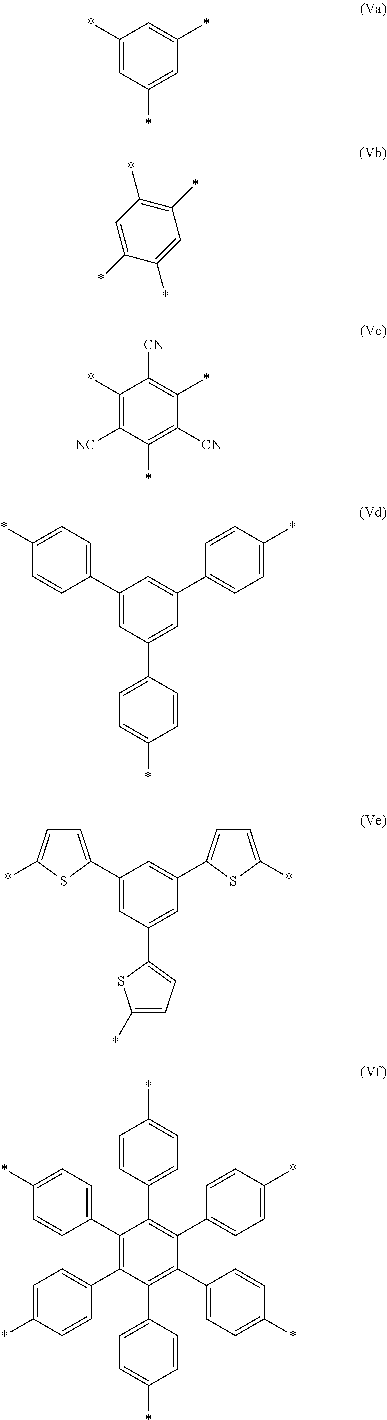 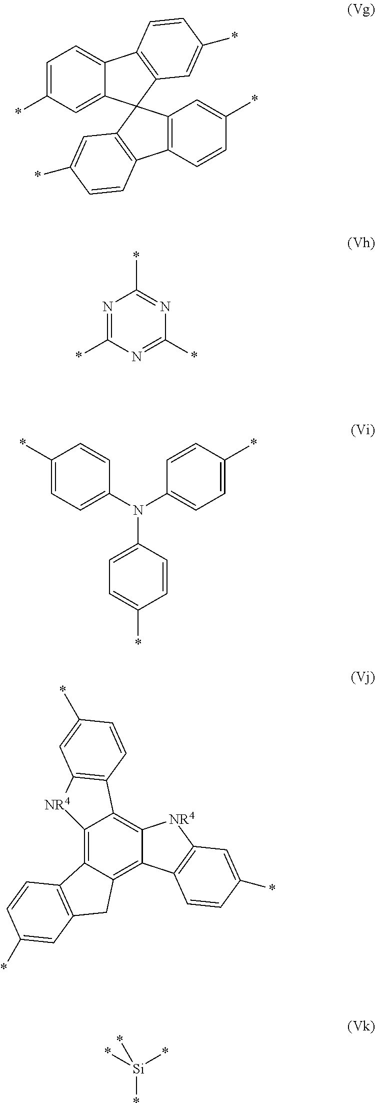 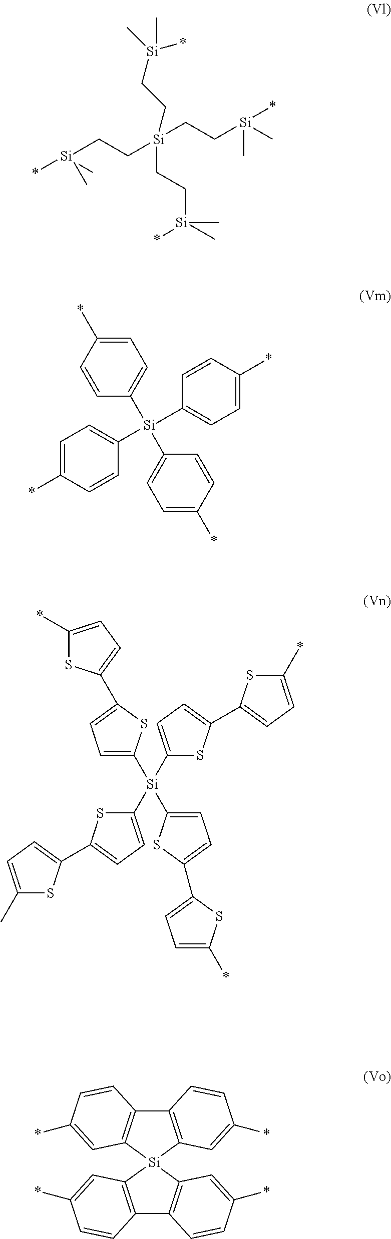 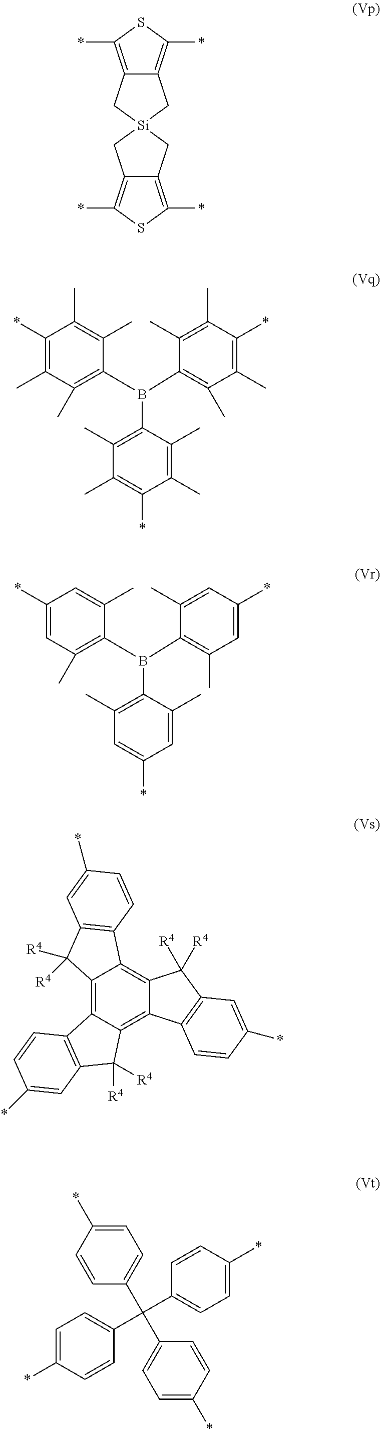
in which
R⁴ represents H or a linear or branched C₁-C₂₀-alkyl group, preferably a C₁-C₁₂-alkyl group, or a linear C₁-C₂₀-alkyl group, preferably C₁-C₁₂-alkyl group, which is optionally interrupted by one or more O or S atoms or silylene, phosphonoyl or phosphoryl groups.

2. Compounds according to claim 1, wherein M represents optionally substituted 2,5-thienylene (IVr): 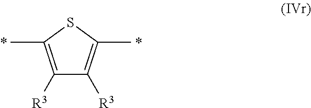
wherein
R³ can be identical or different and represents H or a linear or branched C₁-C₂₀-alkyl group, preferably a C₁-C₁₂-alkyl group, or a linear C₁-C₂₀-alkyl group, preferably C₁-C₁₂-alkyl group, which is optionally interrupted by one or more O or S atoms or silylene, phosphonoyl or phosphoryl groups.

3. Compounds according to claim 2, wherein R³ represents a hydrogen atom.

4. Compounds according claim 1, wherein K represents a branching group of the formula (Ve), (Vg) or (Vi)

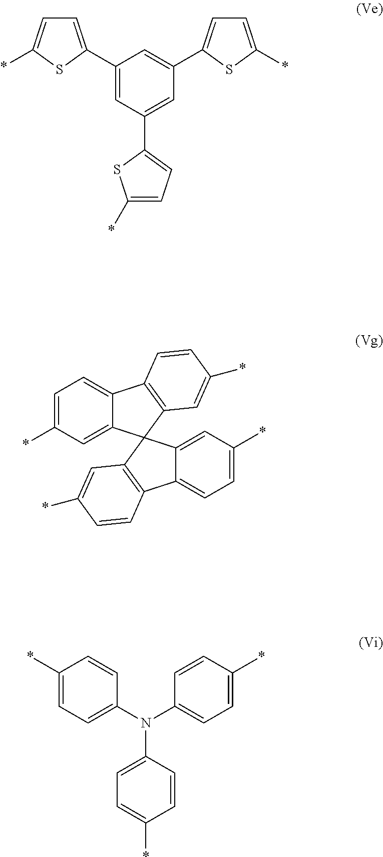 [SMILES: *c1ccc(-c2cc(-c3ccc(*)s3)cc(-c3ccc(*)s3)c2)s1 ; *c1ccc2c(c1)C1(c3cc(*)ccc3-2)c2cc(*)ccc2-c2ccc(*)cc21 ; *c1ccc(N(c2ccc(*)cc2)c2ccc(*)cc2)cc1]

5. Compounds according to claim 4, wherein K represents a branching group of the formula (Vi)

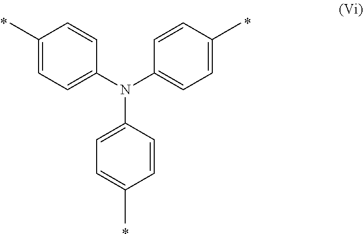

6. Compounds according to claim 5, wherein:
M represents 2,5-thienylene (IVr) 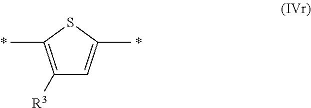
wherein R³ is a hydrogen atom;
x represents 2;
y represents 0;
A represents an acceptor group of the formula (IIIh) 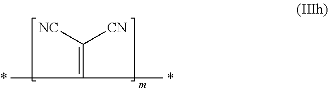
in which m represents 1; and
R represents a —C₆H₁₃ radical.

7. Compounds according to claim 5, wherein:
M represents 2,5-thienylene (IVr) 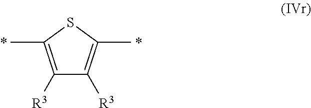
in which R³ represents a hydrogen atom,
x represents 1;
y represents 2;
A represents an acceptor group of the formula (IIIa) 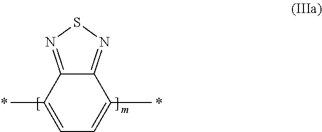
in which m represents 1; and
R represents a radical

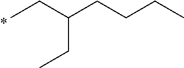

8. A process for the preparation of compounds according to claim 1, wherein
the -[L-R] radical or radicals or synthesis precursors of the -[L-R] radical or radicals are present as an organoboron compound and the branching group K is present as an aryl or heteroaryl halide, or
the -[L-R] radical or radicals or synthesis precursors of the -[L-R] radical or radicals are present as an aryl or heteroaryl halide and the branching group K is present as an organoboron compound,
and the -[L-R] radical or radicals or synthesis precursors of the -[L-R] radical or radicals are bonded to the branching group K via a Suzuki coupling.

9. The process according to claim 8, wherein the organoboron compound employed is either a compound of the general formula (VI) or a compound of the general formula (VII) 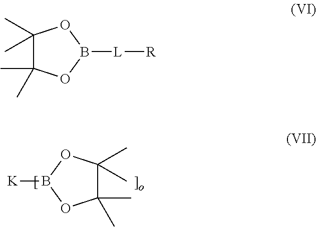
in which o represents an integer from 3 to 6.

10. The process according to claim 8, wherein the aryl or heteroaryl halide employed is either a compound of the general formula (VIII) or a compound of the general formula (IX) 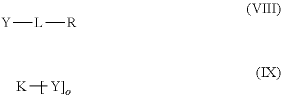
in which o represents an integer from 1 to 5 and Y represents Cl, Br, I or —O—SO₂—R⁶, wherein R⁶ represents a methyl, trifluoromethyl, phenyl or tolyl group.

11. A compoundobtainable by the process according to claim 8.

12. A method of producing an electronic component, the method comprising integrating a semiconducting layer comprising a compound according to claim 1 in an electronic component.

13. The method of claim 13, wherein the compound of claim 1 are employed as a donor group in combination with fullerenes as an acceptor group.

14. A semiconducting layer, comprising a compound of claim 1 applied to a substrate with electrical or electronic structures.

15. The semiconducting layer according to claim 14, wherein the semiconducting layers comprise the compounds according to claim 1 as a donor group and fullerenes as an acceptor group.

16. An electronic component comprising at least one semiconducting layer according to claim 14.

17. The electronic component according to claim 16, wherein the electronic component is an organic solar cell.
